(19) United States
(12) Patent Application Publication
(10) Pub. No.: US 2012/0216946 A1
(43) Pub. Date: Aug. 30, 2012

(54) METHOD OF MANUFACTURING WIRING SUBSTRATE

(75) Inventor: Takaharu HONDO, Chiba-shi (JP)

(73) Assignee: FUJIKURA LTD., Tokyo (JP)

(21) Appl. No.: 13/467,726

(22) Filed: May 9, 2012

Related U.S. Application Data
(63) Continuation of application No. PCT/JP2010/069957, filed on Nov. 9, 2010.

(30) Foreign Application Priority Data
Nov. 10, 2009 (JP) 2009-256922
Nov. 10, 2009 (JP) 2009-257166
Jan. 29, 2010 (JP) 2010-019146

(51) Int. Cl. H05K 3/22; B22D 25/02; B23K 31/02; B32B 37/02

(52) U.S. Cl. 156/182; 427/96.1; 156/60; 164/76.1; 228/176

(57) ABSTRACT

A method of manufacturing a wiring substrate, includes: a step of preparing a first metal circuit layer, one face of the first metal circuit layer has thereon a first conductor circuit and a first interlayer connecting section having a different height from that of the first conductor circuit; and a step of forming a first insulating resin layer covering the one face of the first metal circuit layer so that a tip end of the first interlayer connecting section is exposed.

### CROSS-REFERENCE TO RELATED APPLICATIONS

The application is a Continuation of PCT Application No. PCT/JP2010/069957, filed on Nov. 9, 2010, and claims the benefit of priority from the prior Japanese Patent Applications No. 2009-256922, filed on Nov. 10, 2009; No. 2009-257166, filed on Nov. 10, 2009; and No. 2010-019146, filed on Jan. 29, 2010, the entire contents of which are incorporated herein by reference.

### BACKGROUND OF THE INVENTION

The present invention relates to a method of manufacturing a wiring board for mounting an electronic component.

With downsizing of electronic devices, electronic components built in the electronic devices and wiring boards mounted on the electronic components needs to become smaller. Thus, the miniaturization has been required for the wirings constituted on the wiring boards for transmitting many signals.

Conventionally, the wirings have been formed by a photolithography technique. In the case of the photolithography used for the print wiring level however, it is difficult to provide the miniaturization of the wiring width of 10 μm or less. Thus, such a method has been required to form a more minute wiring width.

As one of the methods to form a more minute wiring width, the imprint method has been known by which a stamper (mold) having a convex pattern for forming a wiring pattern is used to transfer a concave pattern on an insulating layer to fill the transferred concave pattern with conducting material to thereby form a wiring pattern.

For example, Japanese Laid-Open Publication No. 2001-320150 (hereinafter referred to as “Patent Publication 1”) discloses a method of manufacturing a wiring board by which a stamper is used to transfer a concavo-convex pattern on resin to fill the transferred concave section with conducting material to thereby form a conductor circuit.

Specifically, as shown in FIGS. 24(A) to 24(C), a stamper 301 having a concavo-convex section having a wiring pattern is attached to a metal mold for molding. Thereafter, this metal mold is filled with thermoset epoxy resin and is subjected to a transfer molding to thereby form a resin substrate 302 on which a concavo-convex pattern consisting of a concave section 303 and a convex section is transferred.

Next, as shown in FIGS. 24(D) and 24(E), the resin substrate 302 is subjected to an electrolytic plating to form a copper plating film 304 so that the concave section 303 is filled with copper plating. Then, the copper plating film 304 is polished until resin is exposed, thereby forming a wiring section 305.

Japanese Laid-Open Publication No. 2005-108924 (hereinafter referred to as “Patent Publication 2”) discloses a method of manufacturing a wiring board by which a concavo-convex pattern is transferred on resin by a mold having a convex section for forming a conductor circuit and a convex section for forming a via hole to fill the transferred concave section with conducting material to thereby form a conductor circuit.

Specifically, as shown in FIGS. 25(A) to 25(C), interlayer insulating layers 309 are formed on both faces of an insulating substrate 308 including a circuit 306 and a through hole 307. Then, a mold 312 having a convex section 310 for forming a conductor circuit and a convex section 311 for forming a via hole are pushed to the interlayer insulating layer 309 to transfer a concavo-convex pattern. Then, the mold 312 is detached to form a conductor circuit formation groove 313 and a via hole formation groove 314.

Next, as shown in FIGS. 25(D) and 25(E), copper plating films 315 are formed so as to fill the conductor circuit formation groove 313 and the via hole formation groove 314 formed on both faces of the insulating substrate 308. Then, the copper plating films 315 are polished to form a conductor circuit 316 and an interlayer connecting section 317 filling the via hole formation groove 314.

### SUMMARY OF THE INVENTION

In the case of the method disclosed in Patent Publication 1 however, there is a disadvantage in that the resin of the resin substrate 302 is attached to the stamper 301 when the concavo-convex section of the stamper 301 is transferred on the resin substrate 302 and then the stamper 301 is demolded from the resin substrate 302. This disadvantage may cause a deformation of a pattern transferred on the resin substrate 302 or an inconvenience when the resin-attached stamper 301 is used to transfer a concavo-convex pattern on another resin substrate.

In the case of the method disclosed in Patent Publication 2 on the other hand, there is a disadvantage in that the resin of the interlayer insulating layer 309 is attached to the mold 312 when the concavo-convex section of the mold 312 is transferred on the interlayer insulating layer 309 and then the mold 312 is demolded from the interlayer insulating layer 309. This disadvantage may cause a deformation of a pattern transferred on the interlayer insulating layer 309 and an inconvenience when the resin-attached mold 312 is used to transfer a concavo-convex pattern on another interlayer insulating layer.

In view of the above disadvantages, it is an objective of the present invention to provide a method of manufacturing a wiring substrate that can avoid a failure caused by resin attached to a stamper (mold) when the concavo-convex pattern of the stamper (mold) is transferred on an insulating resin layer (interlayer insulating layer) to subsequently demold the stamper (mold) from the insulating resin layer.

An aspect of the present invention inheres in a method of manufacturing a wiring substrate, including: a step of preparing a first metal circuit layer, one face of the first metal circuit layer has thereon a first conductor circuit and a first interlayer connecting section having a different height from that of the first conductor circuit; and a step of forming a first insulating resin layer covering the one face of the first metal circuit layer so that a tip end of the first interlayer connecting section is exposed.

Another aspect of the present invention inheres in a method of manufacturing a wiring substrate, including: a step of forming a metal circuit layer, one face of the metal circuit layer has a first conductor circuit and an interlayer connecting section having a different height from that of the first conductor circuit; a step of forming a soldering layer on a top part of the interlayer connecting section; a step of preparing an insulating resin layer; a step of press-fitting, to one face of the insulating resin layer, the interlayer connecting section in which the first conductor circuit and the soldering layer are formed at the top part to expose the soldering layer from the other face of the insulating resin layer; a step of forming, on the other face of the insulating resin layer, a second conductor circuit abutted to the soldering layer; and a step of melting the soldering layer to form an alloy layer between the interlayer connecting section and the second conductor circuit.

### BRIEF DESCRIPTION OF THE DRAWINGS

FIGS. 1(A) to 1(G) illustrate a method of manufacturing a wiring substrate according to the first embodiment of the present invention. FIG. 1(A) illustrates a metal mold formation step. FIG. 1(B) illustrates a metal circuit layer formation step. FIG. 1(C) illustrates a step of removing the metal circuit layer from the metal mold. FIG. 1(D) illustrates a step of coating the metal circuit layer with liquid insulating resin. FIG. 1(E) illustrates an insulating resin layer integration step to cure the liquid insulating resin so that the liquid insulating resin is integrated with the metal circuit layer. FIG. 1(F) illustrates a metal circuit layer polishing step. FIG. 1(G) illustrates a circuit formation step to form the second conductor circuit on the other face of the insulating resin layer.

FIGS. 2(A) and 2(B) illustrate the metal circuit layer. FIG. 2(A) is a cross-sectional view thereof. FIG. 2(B) is an expanded perspective view illustrating the main part of apart in which the interlayer connecting section is formed.

FIGS. 3(A) to 3(F) illustrate a method of manufacturing a layered wiring substrate according to the second embodiment of the present invention. FIG. 3(A) illustrates a step of coating the concavo-convex section of the second metal circuit layer with liquid insulating resin. FIG. 3(B) illustrates the second insulating resin layer integration step. FIG. 3(C) illustrates a prestep to superpose the double face circuit substrate on the metal circuit layer integrated with the half-cured second insulating resin layer. FIG. 3(D) illustrates a laminate integration step to laminate and integrate the double face circuit substrate and the metal circuit layer integrated with the second insulating resin layer. FIG. 3(E) illustrates a step of peeling the adhesive sheet from the second metal circuit layer. FIG. 3(F) illustrates a step of polishing the second metal circuit layer.

FIGS. 4(A) to 4(D) illustrate another example of a method of manufacturing a layered wiring substrate according to the third embodiment of the present invention. FIG. 4(A) illustrates a step of superposing the second metal circuit layer on the double face circuit substrate coated liquid insulating resin. FIG. 4(B) illustrates step to subject the double face circuit substrate and the second metal circuit layer to a layering integration. FIG. 4(C) illustrates a step of peeling the adhesive sheet from the second metal circuit layer. FIG. 4(D) illustrates step of polishing the second metal circuit layer.

FIGS. 5(A) to 5(G) illustrate a method of manufacturing a wiring substrate according to the fourth embodiment of the present invention. FIG. 5(A) illustrates a metal mold formation step. FIG. 5(B) illustrates a metal circuit layer formation step. FIG. 5(C) illustrates a step of removing the metal circuit layer from the metal mold. FIG. 5(D) illustrates a prestep of integrating the metal circuit layer with the insulating resin layer. FIG. 5(E) illustrates a step of subjecting the metal circuit layer and the insulating resin layer to an insulating resin layer integration step. FIG. 5(F) illustrates a step of polishing the metal circuit layer. FIG. 5(G) is a circuit formation step of forming the second conductor circuit on the other face of the insulating resin layer.

FIGS. 6(A) to 6(F) illustrate a method of manufacturing a layered wiring substrate according to the fifth embodiment of the present invention. FIG. 6(A) illustrates a prestep of superposing the half-cured second insulating resin layer on the double face circuit substrate. FIG. 6(B) illustrates a step of superposing the half-cured second insulating resin layer on the double face circuit substrate. FIG. 6(C) illustrates a prestep of integrating the double face circuit substrate with the second metal circuit layer. FIG. 6(D) illustrates a layering step of layering the second metal circuit layer on the double face circuit substrate. FIG. 6(E) illustrates a step of peeling the adhesive sheet from the second metal circuit layer. FIG. 6(F) illustrates a step of polishing the second metal circuit layer.

FIG. 7 is a cross-sectional view illustrating an example of the wiring substrate according to the sixth embodiment of the present invention.

FIG. 8 is a step cross-sectional view illustrating an example of a method of manufacturing a wiring substrate according to the sixth embodiment of the present invention.

FIG. 9 is another step cross-sectional view following FIG. 8 that illustrates an example of a method of manufacturing a wiring substrate according to the sixth embodiment of the present invention.

FIG. 10 is another step cross-sectional view following

FIG. 9 that illustrates an example of a method of manufacturing a wiring substrate according to the sixth embodiment of the present invention.

FIG. 11 is a perspective view illustrating an example of a method of manufacturing a wiring substrate according to the sixth embodiment of the present invention.

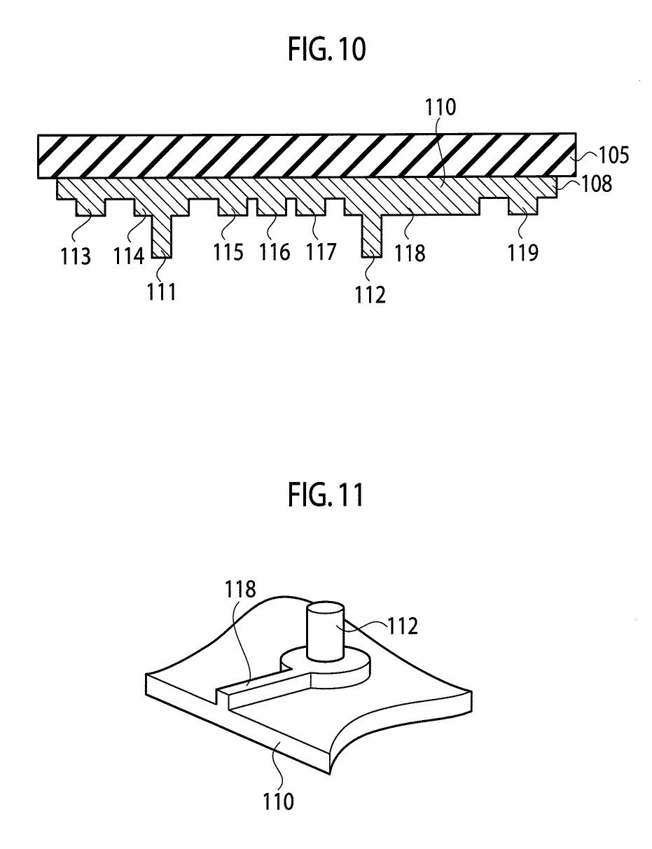

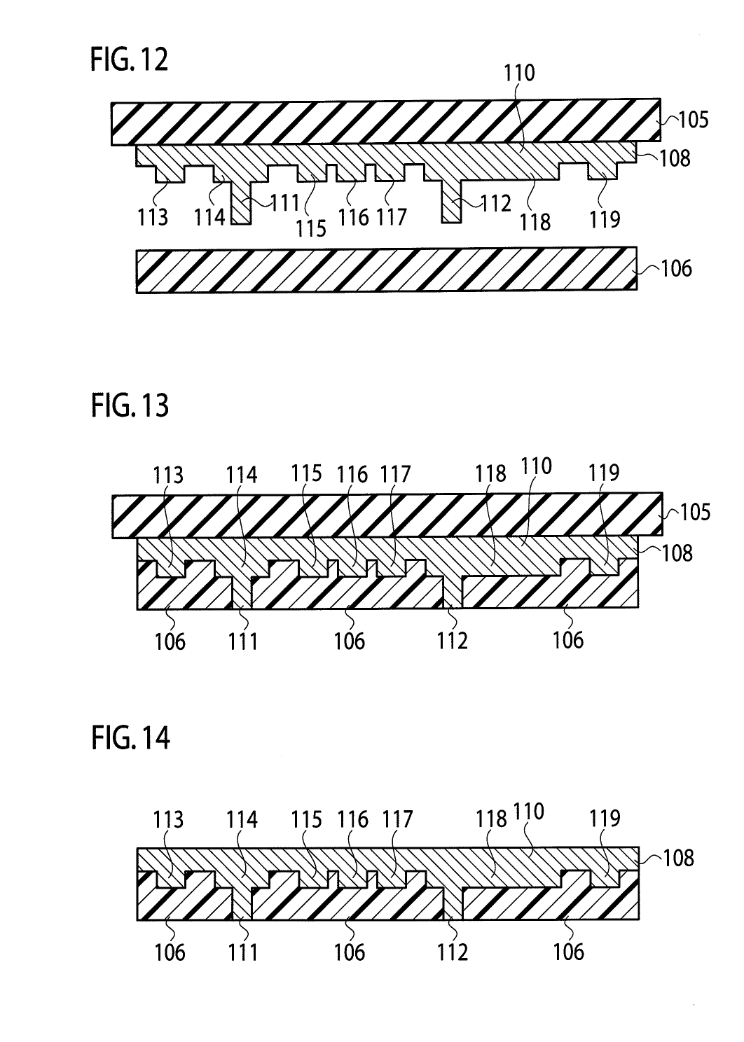

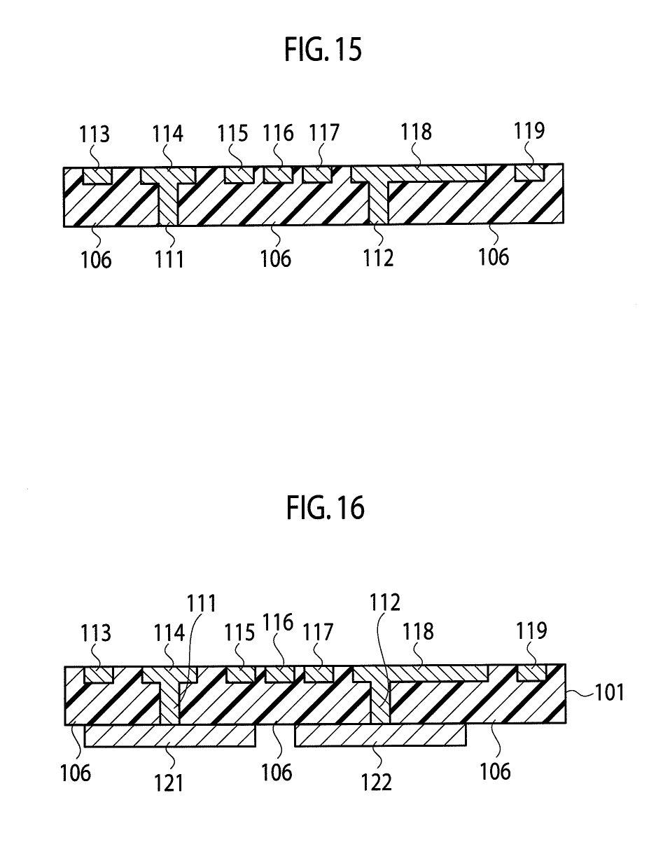

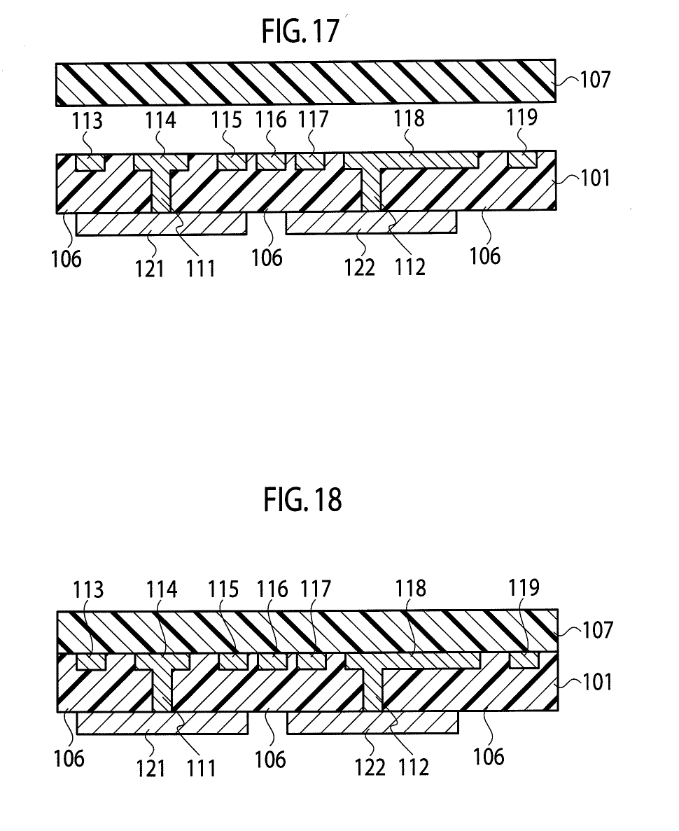

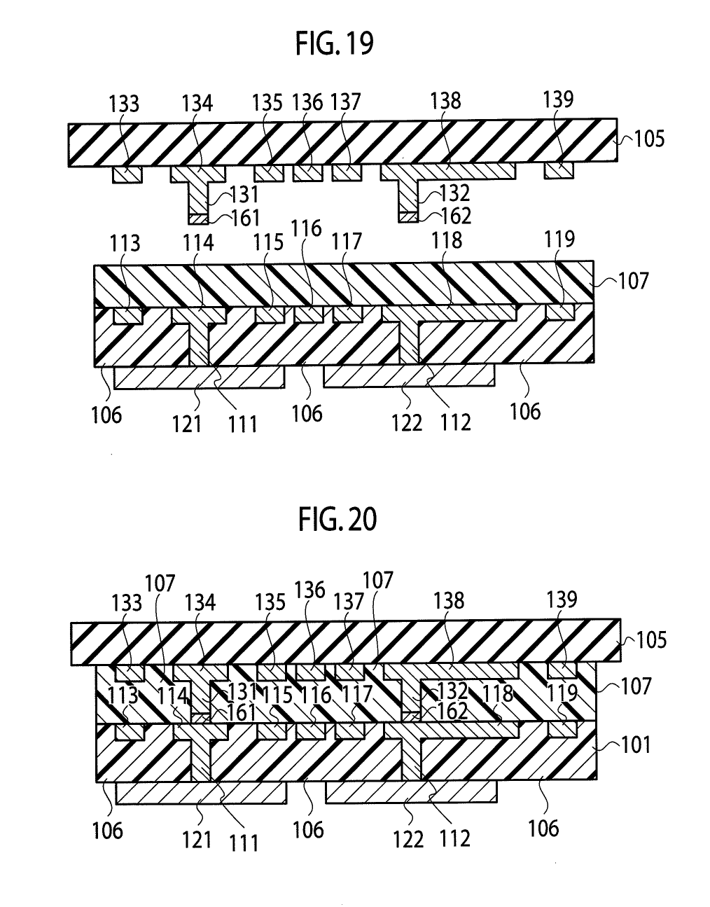

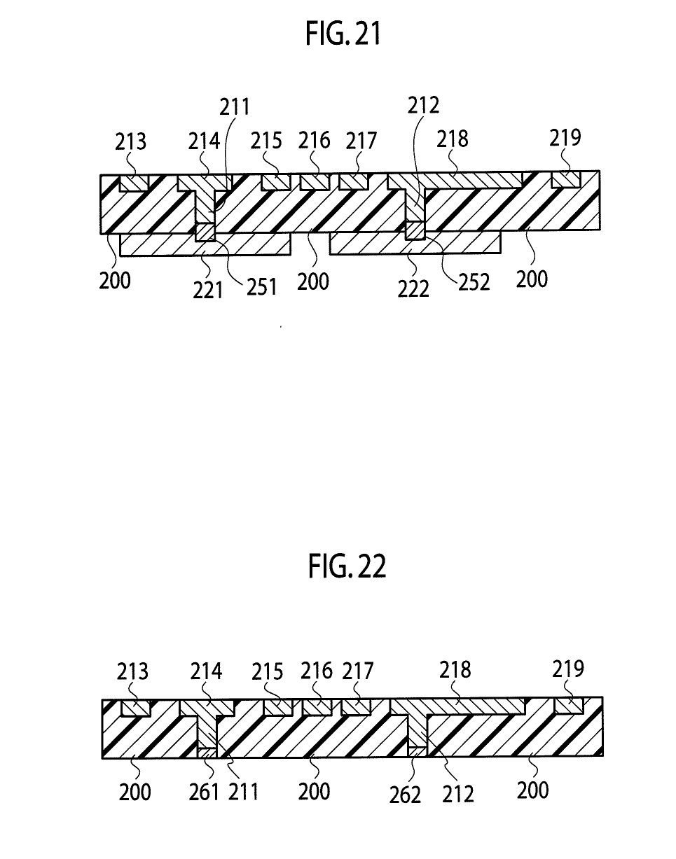

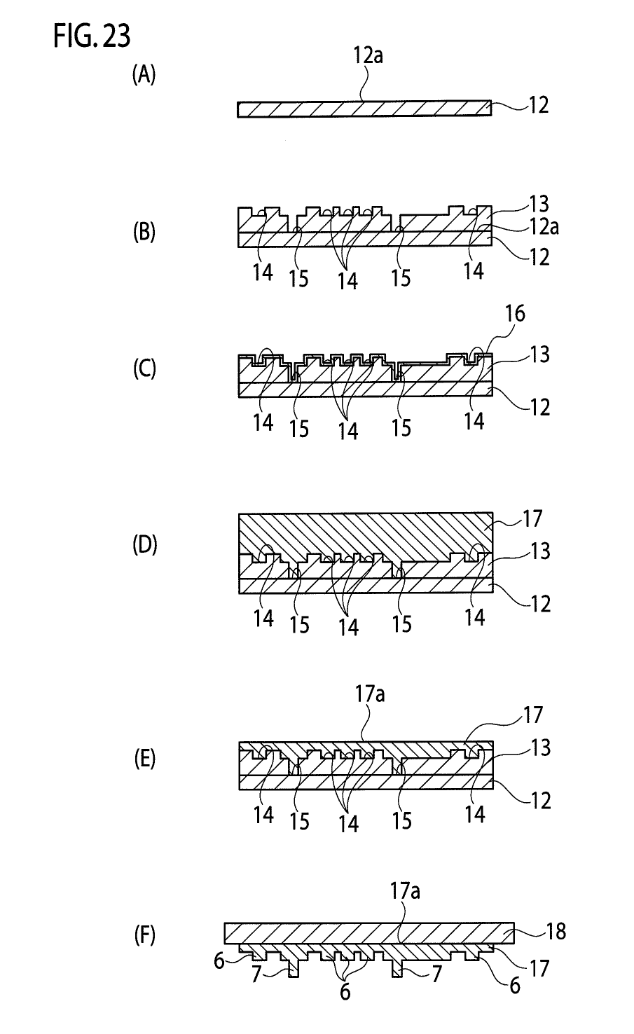

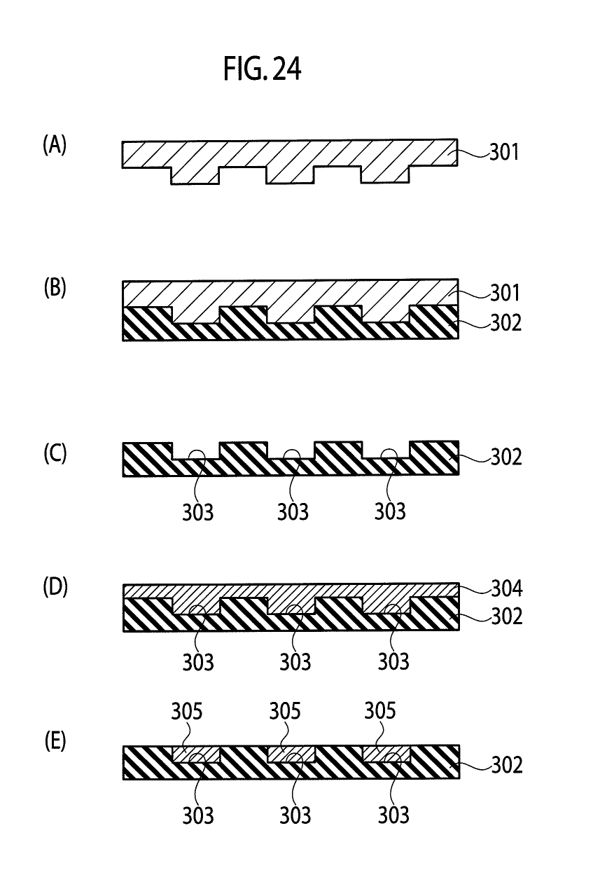

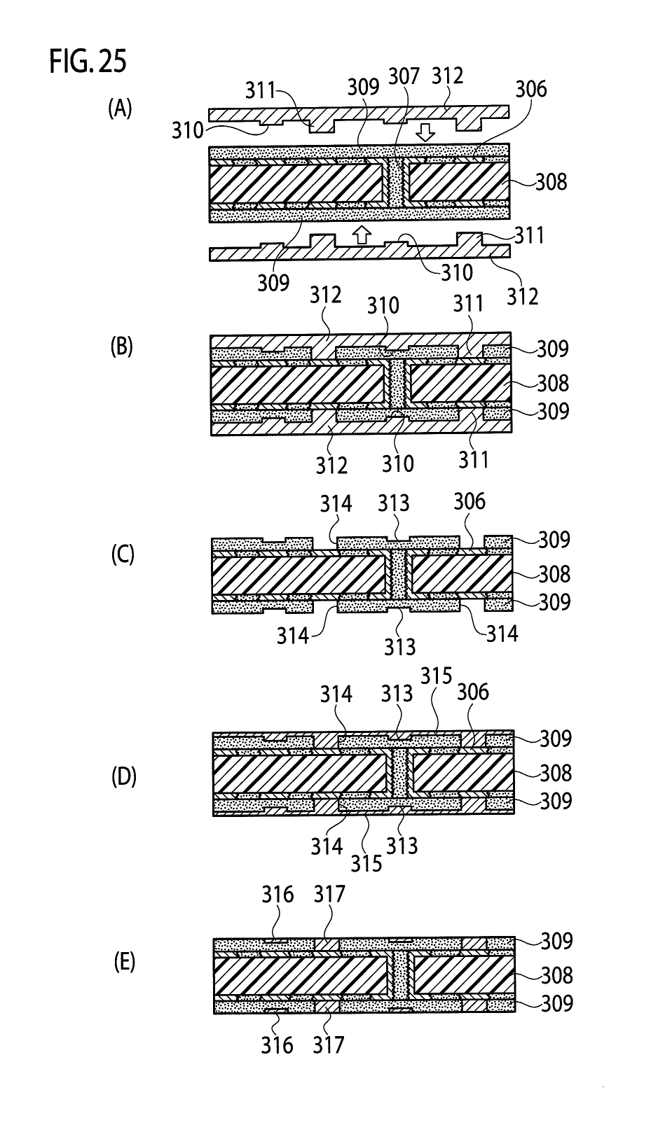

FIG. 12 is another step cross-sectional view following FIG. 10 that illustrates an example of a method of manufacturing a wiring substrate according to the sixth embodiment of the present invention.

FIG. 13 is another step cross-sectional view following FIG. 12 that illustrates an example of a method of manufacturing a wiring substrate according to the sixth embodiment of the present invention.

FIG. 14 is another step cross-sectional view following FIG. 13 that illustrates an example of a method of manufacturing a wiring substrate according to the sixth embodiment of the present invention.

FIG. 15 is another step cross-sectional view following FIG. 14 that illustrates an example of a method of manufacturing a wiring substrate according to the sixth embodiment of the present invention.

FIG. 16 is another step cross-sectional view following FIG. 15 that illustrates an example of a method of manufacturing a wiring substrate according to the sixth embodiment of the present invention.

FIG. 17 is another step cross-sectional view following FIG. 16 that illustrates an example of a method of manufacturing a wiring substrate according to the sixth embodiment of the present invention.

FIG. 18 is another step cross-sectional view following FIG. 17 that illustrates an example of a method of manufacturing a wiring substrate according to the sixth embodiment of the present invention.

FIG. 19 is another step cross-sectional view following

FIG. 18 that illustrates an example of a method of manufacturing a wiring substrate according to the sixth embodiment of the present invention.

FIG. 20 is another step cross-sectional view following FIG. 19 that illustrates an example of a method of manufacturing a wiring substrate according to the sixth embodiment of the present invention.

FIG. 21 is a cross-sectional view illustrating an example of the wiring substrate according to the seventh embodiment of the present invention.

FIG. 22 is a step cross-sectional view illustrating an example of a method of manufacturing a wiring substrate according to the seventh embodiment of the present invention.

FIGS. 23(A) to 23(F) are a step diagram illustrating a step of forming a metal circuit layer having a minute conductor circuit pattern. FIG. 23(A) illustrates a silicon wafer preparation step. FIG. 23(B) illustrates a concavo-convex pattern formation step by resist. FIG. 23(C) illustrates a seed layer formation step. FIG. 23(D) illustrates a plating step. FIG. 23(E) illustrates a plating polishing step. FIG. 23(F) illustrates a step of removing the metal circuit layer from the silicon wafer.

FIG. 24 is a conventional step diagram illustrating a wiring substrate manufacture step of transferring a concavo-convex pattern on resin by a stamper to fill the transferred concave section with conducting material to thereby form a conductor circuit.

FIG. 25 is a conventional step diagram illustrating a wiring substrate manufacture step of using a mold having a convex section for forming a conductor circuit and a convex section for forming a via hole to transfer a concavo-convex pattern on resin to fill the transferred concave section with conducting material to thereby form the conductor circuit.

### DETAILED DESCRIPTION OF THE EMBODIMENT OF THE INVENTION

First to seventh embodiments will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set fourth such as specific layer thickness, etc. to provide a thorough understanding. However, it will be obvious to those skilled in the art that the present invention may be practiced without such specific details. In other instances, well-known circuits have been shown in block diagram form in order not to obscure the present invention in unnecessary detail.

### First Embodiment

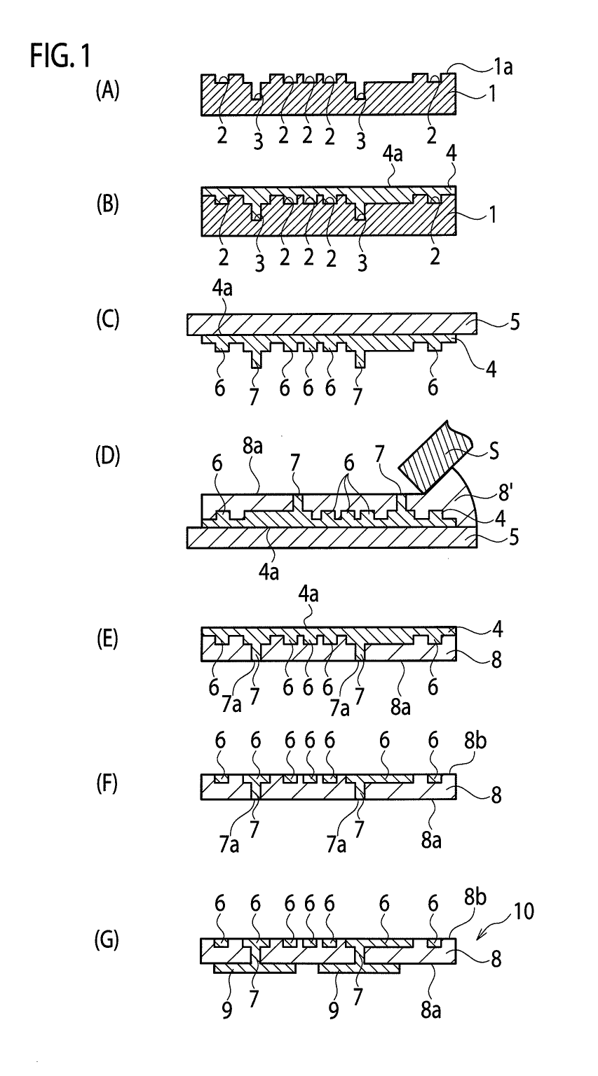

FIGS. 1(A) to 1(G) are a step diagram sequentially illustrating the manufacture steps of the wiring substrate of the first embodiment. FIG. 1(A) illustrates a metal mold formation step. FIG. 1(B) illustrates a metal circuit layer formation step. FIG. 1(C) illustrates a step of removing the metal circuit layer from the metal mold. FIG. 1(D) illustrates a step of coating the metal circuit layer with liquid insulating resin. FIG. 1(E) is an insulating resin layer integration step of curing the liquid insulating resin to integrate the metal circuit layer with the insulating resin layer. FIG. 1(F) illustrates a step of polishing the metal circuit layer. FIG. 1(G) illustrates a circuit formation step of forming the second conductor circuit on the other face of the insulating resin layer.

In order to manufacture a wiring substrate, the metal mold formation step and the metal circuit layer formation step shown in FIG. 1(A) and FIG. 1(B) are firstly performed. First, a metal mold 1 is prepared. The metal mold 1 is made of material that can be easily demolded from conducting metal material (plating or conducting paste) or that is coated with a surface treatment. The metal mold 1 can be formed, for example, by nickel electrocasting, silicon, or quartz for example. The surface treatment may be performed by silane coupling agent such as fluoride.

Next, as shown in FIG. 1(A), the one face 1a of the metal mold 1 is caused to include a concave section 2 (hereinafter referred to as the first concave section) for forming a conductor circuit and a concave section 3 (hereinafter referred to as the second concave section) for forming an interlayer connecting section having a deeper depth than that of this first concave section 2. These concave sections 2 and 3 can be formed, for example, by an electron beam processing or a femtosecond laser processing by which microfabrication on the order of tens of μm can be performed. By using these processing techniques to form the concave sections 2 and 3, the first concave section 2 and the second concave section 3 can be formed with improved groove processing accuracy and formation position accuracy when compared with the case of a CO₂ laser or UV laser processing technique used for a print wiring substrate. The first concave section 2 is a concave section in accordance with a conductor circuit pattern to be manufactured. The second concave section 3 is a concave section in accordance with a via for electrically connecting the first conductor circuit and the second conductor circuit finally formed on both faces of the insulating resin layer.

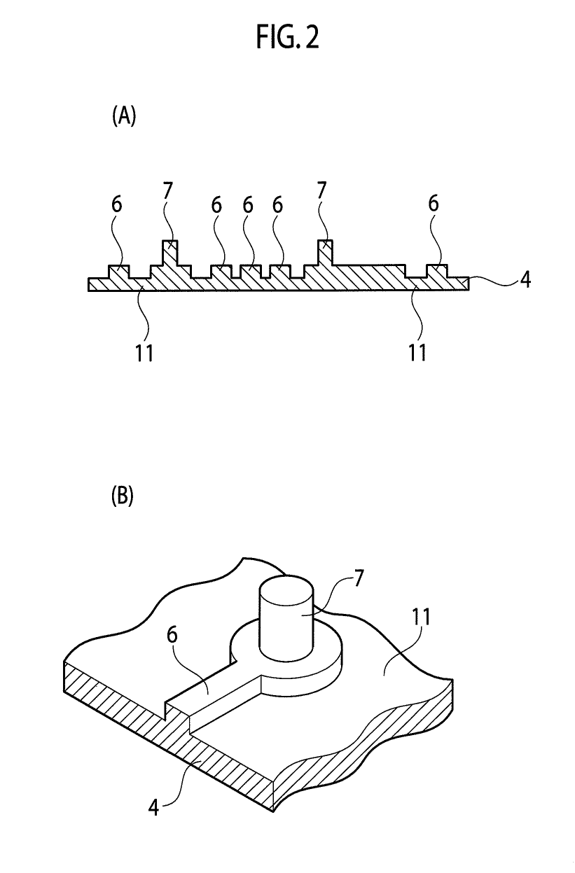

Next, as shown in FIG. 1(B), the first concave section 2 and the second concave section 3 are filed with conducting metal material. Specifically, the first concave section 2 and the second concave section 3 are filed with the conducting metal material by sputtering copper or nickel for example on the one face 1a of the metal mold 1 to subsequently plate the one face 1a. Alternatively, carbon or palladium is plated on the one face 1a of the metal mold 1 by a Direct Plating Processing (DPP). Thereafter, the first concave section 2 and the second concave section 3 are filled with the conducting metal material by plating gold or copper or nickel for example on the first concave section 2 and the second concave section 3 or by printing copper or silver nanopaste (conducting paste) on the first concave section 2 and the second concave section 3. Then, the conducting metal material filled in the first concave section 2 and the second concave section 3 is cured. This consequently forms, as shown in FIG. 2, a metal circuit layer 4 in which the first conductor circuit 6 (which will be described later) and an interlayer connecting section 7 functioning as a via are connected by a conductor connecting section 11.

Next, an insulating resin layer integration step shown in FIGS. 1(C) to 1(E) is performed to integrate the metal circuit layer 4 with the insulating resin layer. A circuit layer removal member 5 such as an adhesive sheet or a suction sheet is adhered to the other face 4a at an opposite side of the concavo-convex face of the metal circuit layer 4. Then, this circuit layer removal member 5 is peeled to remove, as shown in FIG. 1(C), the metal circuit layer 4 from the metal mold 1. The metal circuit layer 4 removed from the metal mold 1 has a concavo-convex face in which the concavo-convex pattern formed in the metal mold 1 has a transferred concavo-convex shape. The metal circuit layer 4 functions as a circuit layer in which the first conductor circuit 6 is integrated with the interlayer connecting section 7 functioning as a via. The first conductor circuit 6 has a lower height than that of the interlayer connecting section 7 and has a different height from that of the interlayer connecting section 7. In other words, the interlayer connecting section 7 is a convex section having a higher height than that of the first conductor circuit 6.

Next, as shown in FIG. 1(D), liquid insulating resin 8′ is coated on the concavo-convex section of the metal circuit layer 4 so that this concavo-convex section is an upper face and is planarized. In order to coat the liquid insulating resin 8′, the liquid insulating resin 8′ supplied on the metal circuit layer 4 is planarized by the squeegee S so as to remove any concavo-convex section to thereby planarize the one face 8a. The liquid insulating resin 8′ may be, for example, polyimide varnish. Next, this liquid insulating resin 8′ is cured by heating or UV irradiation. The heating was performed in air in an oven at a temperature of 300 degrees C. and for a heating period of one hour. 30 minutes are required to reach the heating temperature of 300 degrees C. and 60 minutes are required to cool the liquid insulating resin 8′ to room temperature.

When the liquid insulating resin 8′ is cured, then the circuit layer removal member 5 is removed from the metal circuit layer 4. As a result, as shown in FIG. 1(E), the insulating resin layer 8 including the cured liquid insulating resin 8′ is integrated with the metal circuit layer 4. The first conductor circuit 6 is formed not to protrude from the other face 8b of the insulating resin layer 8. The interlayer connecting section 7 penetrates the insulating resin layer 8 in the thickness direction. The tip end section 7a thereof is exposed to have the same height as that of the one face 8a (i.e., to be flush to each other).

Next, the polishing step shown in FIG. 1(F) is performed. Specifically, the metal circuit layer 4 formed on the other face 8b at an opposite side of the resin-coated-side face 8a of the metal circuit layer 4 is polished until resin is exposed. The polishing may be performed by polishing the metal circuit layer 4 with a grinding stone or by melting the metal circuit layer 4 by etching. As a result, the connected conductor connecting section 11 (the conductor portion other than the circuit) is removed to thereby form the first conductor circuit 6 and the interlayer connecting section 7. The interlayer connecting section 7 is conductive with the first conductor circuit 6 and penetrates the insulating resin layer 8 to expose the tip end section 7a at the one face 8a.

Next, the circuit formation step shown in FIG. 1(G) is performed. Specifically, the second conductor circuit 9 is formed on the one face 8a of the insulating resin layer 8. The second conductor circuit 9 is conductive with the first conductor circuit 6 formed on the other face 8b of the insulating resin layer 8 via the interlayer connecting section 7. In order to form the second conductor circuit 9, the second conductor circuit 9 is positioned to the interlayer connecting section 7 so as to be connected to the interlayer connecting section 7 and a wiring pattern is formed by photolithography or printing for example. For example, in the semiadditive process, a seed layer is formed on the lower face of the insulating resin layer 8 and then resist is coated thereon. Then, the photolithography technique is used to pattern resist. Then, copper electroplating is performed to subsequently remove the resist and the seed layer to thereby form the second conductor circuit 9. Alternatively, a printing plate also may be used to print and sinter conducting paste on the lower face of the insulating resin layer 8 to thereby form the second conductor circuit 9. In the first embodiment of the present invention, the semiadditive process was used to form wiring pattern to have a wiring width of 10 μm and a space between wirings of 10 μm and a land diameter of 80 μm. By the formation as described above, a double face circuit substrate 10 is obtained in which the first conductor circuit 6 is connected via the interlayer connecting section 7 to the second conductor circuit 9. Then, solder resist or a coverlay is provided as required on a surface of this double face circuit substrate 10.

The polishing step shown in FIG. 1(F) can be omitted if an excessive portion as the conductor connecting section 11 can be eliminated by optimizing the conditions to fill the conducting metal material in the concave sections 2 and 3 formed in the metal mold 1 of FIG. 1(B).

In the first embodiment, the conducting metal material is filled and cured in the first concave section 2 and the second concave section 3 formed in the metal mold 1 to form the metal circuit layer 4 and the liquid insulating resin 8′ is coated and cured so as to fill the concavo-convex section of the metal circuit layer 4 to thereby integrate the insulating resin layer 8 with the metal circuit layer 4. Thus, this metal circuit layer 4 itself functions as the first conductor circuit 6 and the interlayer connecting section 7. The interlayer connecting section 7 functions as a via that electrically connects the first conductor circuits 6 to the second conductor circuit 9, the first and second conductor circuits being formed on respective faces of the insulating resin layer 8. This consequently eliminates the need as in the conventional case of using a stamper (mold) to transfer a concavo-convex pattern on insulating resin to subsequently subject the resin to a plating process for example to thereby form a conductor circuit and an interlayer connecting section. Thus, there is no more need to perform a step of manufacturing a stamper (mold). This can consequently prevent a failure caused by resin being attached to a stamper (mold), because a situation will not occur in which the resin is being attached to the stamper (mold) when a stamper (mold) is demolded from the insulating resin layer. Furthermore, a plating step will also not be required to fill the concave section transferred on the insulating resin layer with the conducting material. Thus, the manufacture step can be simplified significantly and the cost can be proportionally reduced.

Also according to the first embodiment, the first conductor circuit 6 and the interlayer connecting section 7 can be simultaneously formed by a single step. Thus, when compared with the conventional method to separately form the first conductor circuit 6 and the interlayer connecting section 7, the first conductor circuit 6 and the interlayer connecting section 7 can be positioned with an improved accuracy.

Also according to the first embodiment, the liquid insulating resin 8′ is coated and cured so as to fill the concavo-convex section of the metal circuit layer 4 to thereby form the insulating resin layer 8 integrated with the metal circuit layer 4. Thus, this liquid insulating resin 8′ thus coated can avoid the breakage of the concavo-convex section (the first conductor circuit 6 and the interlayer connecting section 7) formed on the metal circuit layer 4. Specifically, the coated liquid insulating resin 8′ can prevent a high load from being applied to the concavo-convex section of the metal circuit layer 4, thus avoiding the breakage of the concavo-convex section.

Also according to the first embodiment, by the use of the conducting paste of conducting metal material filled in the first concave section 2 and the second concave section 3 formed on the metal mold 1, the metal circuit layer 4 can be easily formed without causing increased manhours.

### Second Embodiment

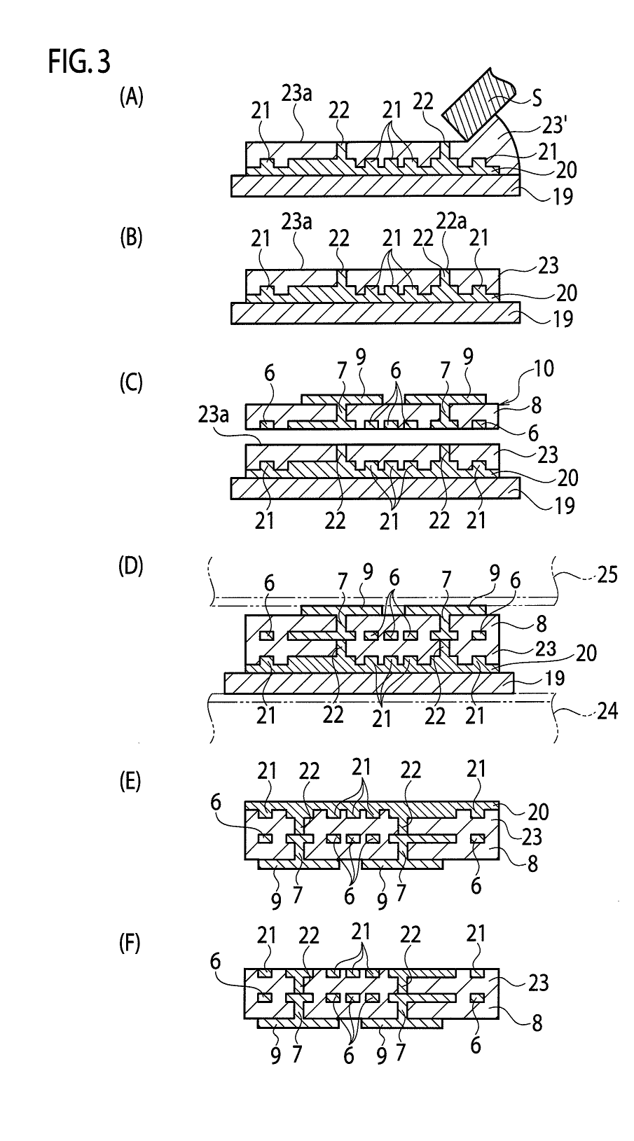

FIGS. 3(A) to 3(F) illustrate a method of manufacturing a layered wiring substrate of the second embodiment. FIG. 3(A) illustrates a step of coating liquid insulating resin on the concavo-convex section of the second metal circuit layer. FIG. 3(B) illustrates the second insulating resin layer integration step. FIG. 3(C) illustrates a prestep of superposing the double face circuit substrate on the metal circuit layer integrated with the half-cured second insulating resin layer. FIG. 3(D) illustrates a laminate integration step to laminate and integrate the double face circuit substrate and the metal circuit layer integrated with the second insulating resin layer. FIG. 3(E) illustrates a step of peeling the adhesive sheet from the second metal circuit layer. FIG. 3(F) illustrates a step of polishing the second metal circuit layer.

The second embodiment is an example in which another circuit is further layered on the double face circuit substrate 10 manufactured in the first embodiment to manufacture a layered wiring substrate. In the second embodiment, the steps up to the step of forming the double face circuit substrate 10 are the same as those in the first embodiment. Thus, the metal circuit layer formation step of the first embodiment will be called as the first metal circuit layer formation step and the metal circuit layer 4 will be called as the first metal circuit layer 4. The insulating resin layer integration step of the first embodiment will be called as the first insulating resin layer integration step. The insulating resin layer will be called as the first insulating resin layer. The polishing step of the first embodiment will be called as the first polishing step. The interlayer connecting section 7 will be called as the first interlayer connecting section 7.

First, the respective manufacture steps of the first embodiment (the first metal circuit layer formation step, the first insulating resin layer integration step, and the first polishing step, and the double face circuit substrate formation step) are performed to thereby prepare the double face circuit substrate 10. The double face circuit substrate 10 is structured so that each face of the first insulating resin layer 8 has the first conductor circuit 6 and the first interlayer connecting section 7. The first interlayer connecting section 7 has the second conductor circuit 9 and is provided to penetrate the first insulating resin layer 8 to electrically connect the first conductor circuit 6 to the second conductor circuit 9.

Next, the second metal circuit layer formation step is performed to form the second metal circuit layer. Specifically, the same step as the metal circuit layer formation step in the first embodiment to form the first metal circuit layer 4 is performed. Specifically, a concave section for forming a conductor circuit and a concave section for forming an interlayer connecting section having a deeper depth than that of this concave section are formed in one face of the metal mold. Then, these concave sections are filled with conducting metal material and are cured to thereby form the second metal circuit layer. The second metal circuit layer has the same shape as that of the first metal circuit layer 4 prepared in the first embodiment. Thus, the same metal mold 1 as that in FIG. 1(A) is used. When the second metal circuit layer having a different shape from that of the first metal circuit layer 4 is prepared, a different metal mold from that in FIG. 1(A) is used.

Next, the second metal circuit layer is adhered by a circuit layer removal member (e.g., an adhesive sheet) and is removed from the metal mold. FIG. 3(A) illustrates the second metal circuit layer 20 adhered on the circuit layer removal member 19. The second metal circuit layer 20 is integrated with the third conductor circuit 21 and the second interlayer connecting section 22 functioning as a via. The second interlayer connecting section 22 has a higher height than that of the third conductor circuit 21.

Next, the second insulating resin layer integration step is performed. Specifically, as shown in FIG. 3(A), liquid insulating resin 23′ is coated on the concavo-convex section of the second metal circuit layer 20 so that this concavo-convex section is an upper face and is planarized. In order to coat the liquid insulating resin 23′, the liquid insulating resin 23′ supplied on the second metal circuit layer 20 is planarized by the squeegee S so as to remove any concavo-convex section to thereby planarize the one face 23a. FIG. 3(B) illustrates the liquid insulating resin 23′ thus planarized. The planarized liquid insulating resin 23′ functions as the half-cured second insulating resin layer 23. The liquid insulating resin 23′ to be used may be polyimide varnish used in the first embodiment. The planarized liquid insulating resin 23′ also may function as the half-cured second insulating resin layer 23 by being heated as required to adjust the curing level.

Next, a layering integration step is performed to subject the double face circuit substrate 10 and the second metal circuit layer 20 integrated with the second insulating resin layer to a layering integration. Specifically, as shown in FIG. 3(C), the double face circuit substrate 10 and the second metal circuit layer 20 are positioned by superposing, on the one face 23a of the half-cured second insulating resin layer 23 as a superposing face, the face of the double face circuit substrate 10 on which the first conductor circuit 6 is formed. The positioning is performed by an image recognition or pin alignment for example.

Then, as shown in FIG. 3(D), the double face circuit substrate 10 attached to the metal molds 24 and 25 and the second metal circuit layer 20 integrated with the second insulating resin layer are heated and pressurized to cure the half-cured second insulating resin layer 23 to thereby subject the former and the latter to a layering integration. As s result, the second interlayer connecting section 22 is abutted to a land of the first conductor circuit 6. Thus, the second conductor circuit 9 is electrically connected to the third conductor circuit 21 via the first interlayer connecting section 7 and the second interlayer connecting section 22.

Next, the circuit layer removal member 19 is removed from the second metal circuit layer 20. FIG. 3(E) illustrates the circuit layer removal member 19 thus removed. In FIG. 3(E), the second metal circuit layer 20 is inverted upside down so that the second metal circuit layer 20 is at the upper side. Then, the second polishing step is performed to polish the second metal circuit layer 20. The second polishing step is performed as in the first polishing step of the first embodiment by polishing the second metal circuit layer 20 by a grinding stone or etching until resin is exposed. The result is as shown in FIG. 3(F) in which the connected conductor connecting section 11 (the conductor portion other than the circuit) is removed to thereby form the third conductor circuit 21 and the second interlayer connecting section 22. The second interlayer connecting section 22 is conductive with the third conductor circuit 21 and penetrates the second insulating resin layer 23 to be electrically connected to the first conductor circuit 6.

The layered wiring substrate thus manufactured is configured so that the first conductor circuit 6 and the second conductor circuit 9 are electrically connected by the first interlayer connecting section 7 functioning as a via the first conductor circuit 6 and the third conductor circuit 21 are electrically connected by the second interlayer connecting section 22 also functioning as a via.

In the second embodiment, a conductor circuit can be multilayered by the following procedure without requiring complicated steps. Specifically, a step is performed to simultaneously form the first conductor circuit 6 and the first interlayer connecting section 7 by a metal mold to thereby form the double face circuit substrate 10. Then, in the double face circuit substrate 10, the liquid insulating resin 23′ is coated so as to fill the concavo-convex section of the second metal circuit layer 20 and is half-cured to thereby provide the half-cured second insulating resin layer 23. Then, the half-cured second insulating resin layer 23 is superposed. Then, the resultant structure is pressurized and heated for integration. Also according to the manufacture method of the second embodiment, a conductor circuit of four or more layers can be formed.

In the second embodiment, as in the first embodiment, the metal circuit layer itself constitutes a conductor circuit and an interlayer connecting section as a via. Thus, there is no more need as in the conventional case of using a stamper (mold) to transfer a concavo-convex pattern on insulating resin to subsequently subject the resin to a plating process for example to thereby form a conductor circuit and an interlayer connecting section. Thus, a step to manufacture a stamper (mold) can be eliminated. This can consequently prevent a failure caused by resin being attached to a stamper (mold), because a situation will not occur in which the resin is being attached to the stamper (mold) when a stamper (mold) is demolded from the insulating resin layer. Furthermore, a plating step will also not be required to fill the concave section of the insulating resin layer on which the concavo-convex pattern of the stamper (mold) is transferred. Thus, the manufacture step can be simplified significantly and the cost can be proportionally reduced.

In the second embodiment, as in the first embodiment, the first conductor circuit 6 and the first interlayer connecting section 7, the third conductor circuit 21, and the second interlayer connecting section 22 can be simultaneously and collectively formed. Thus, when compared with the conventional method of separately forming the first conductor circuit 6 and the first interlayer connecting section 7, the third conductor circuit 21, and the second interlayer connecting section 22, the first conductor circuit 6 and the first interlayer connecting section 7, the third conductor circuit 21, and the second interlayer connecting section 22 can be positioned with an improved accuracy.

### Third Embodiment

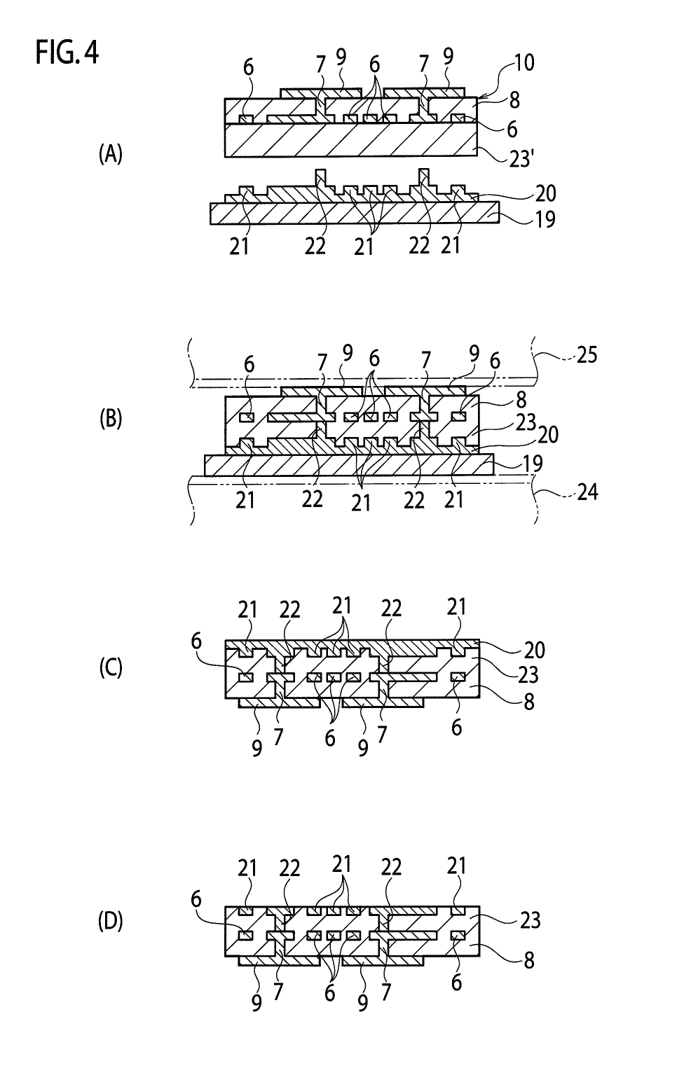

FIGS. 4(A) to 4(D) illustrate a method of manufacturing a layered wiring substrate of the third embodiment. FIG. 4(A) illustrates a step of superposing the second metal circuit layer on a double face circuit substrate coated with liquid insulating resin. FIG. 4(B) is a layering integration step of subjecting the double face circuit substrate and the second metal circuit layer to a layering integration. FIG. 4(C) illustrates a step of peeling an adhesive sheet from the second metal circuit layer. FIG. 4(D) illustrates a step of polishing the second metal circuit layer.

The third embodiment is different from the second embodiment in the following point. Specifically, the steps shown in FIGS. 3(A) to 3(C) of coating the liquid insulating resin 23′ on the second metal circuit layer 20 to subject the double face circuit substrate 10 to a layering integration are substituted with a step as shown in FIG. 4(A) to coat the liquid insulating resin 23′ on the face of the double face circuit substrate 10 on which the first conductor circuit 6 is formed to subsequently place the second metal circuit layer 20 so as to be opposed to the double face circuit substrate 10 coated with the liquid insulating resin 23′.

Next, as shown in FIG. 4(B), the double face circuit substrate 10 and the second metal circuit layer 20 attached to the metal molds 24 and 25 are superposed via the liquid insulating resin 23′ and are heated and pressurized. As a result, the liquid insulating resin 23′ is cured and the former and the latter are subjected to a layering integration. Next, as shown in FIG. 4(C), the circuit layer removal member 19 as an adhesive sheet is removed from the layered wiring substrate obtained through the layering integration. Then, the second metal circuit layer 20 is polished until resin is exposed. As a result, as shown in FIG. 4(D), the connected conductor connecting section 11 (the conductor portion other than the circuit) is removed to thereby form the third conductor circuit 21 and the second interlayer connecting section 22. The second interlayer connecting section 22 is conductive with the third conductor circuit 21 and that penetrates the second insulating resin layer 23 obtained by curing the liquid insulating resin 23′ to be electrically connected to a land of the first conductor circuit 6.

### Fourth Embodiment

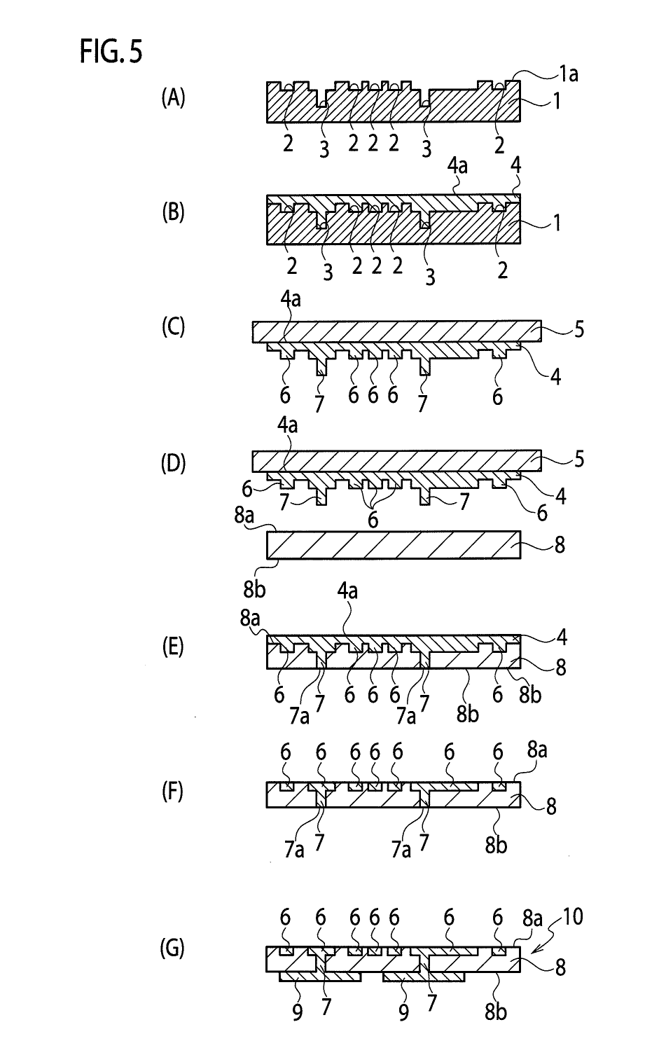

FIGS. 5(A) to 5(G) are a step diagram illustrating the fourth embodiment and sequentially illustrating the steps of manufacturing a wiring substrate using the present invention. In order to manufacture a wiring substrate, a metal mold formation step and a metal circuit layer formation step shown in FIGS. 5(A) and 5(B) are performed. First, the metal mold 1 is prepared. The metal mold 1 is made of material that can be easily demolded from conducting metal material (plating or conducting paste) or that is coated with a surface treatment. The metal mold 1 can be formed, for example, by nickel electrocasting, silicon, or quartz for example. The surface treatment may be performed by silane coupling agent such as fluoride.

Next, as shown in FIG. 5(A), the one face 1a of the metal mold 1 is caused to include a concave section 2 (hereinafter referred to as the first concave section) for forming a conductor circuit and a concave section 3 (hereinafter referred to as the second concave section) for forming an interlayer connecting section having a deeper depth than that of this first concave section 2. These concave sections 2 and 3 can be formed, for example, by microfabrication (e.g., electron beam processing or femtosecond laser processing). By using these processing techniques to form the concave sections 2 and 3, the first concave section 2 and the second concave section 3 can be formed with improved groove processing accuracy and formation position accuracy when compared with the case of a CO₂ laser or UV laser processing technique used for a print wiring substrate. The first concave section 2 is a concave section in accordance with a conductor circuit pattern to be manufactured. The second concave section 3 is a concave section that corresponds as a via for electrically connecting the first conductor circuit to the second conductor circuit, the first and second conductor circuits being finally formed on respective faces of the insulating resin layer.

Next, as shown in FIG. 5(B), the first concave section 2 and the second concave section 3 are filled with conducting metal material. Specifically, the first concave section 2 and the second concave section 3 are filed with the conducting metal material by sputtering copper or nickel for example on the one face 1a of the metal mold 1 to subsequently plate the one face 1a. Alternatively, carbon or palladium is plated on the one face 1a of the metal mold 1 by a Direct Plating Processing (DPP). Thereafter, the first concave section 2 and the second concave section 3 are filled with the conducting metal material by plating gold or copper or nickel for example on the first concave section 2 and the second concave section 3 or by printing copper or silver nanopaste (conducting paste) on the first concave section 2 and the second concave section 3. Then, the conducting metal material filled in the first concave section 2 and the second concave section 3 is cured. This consequently forms, as shown in FIG. 2, the metal circuit layer 4 in which the first conductor circuit 6 shown in FIG. 2 and the interlayer connecting section 7 functioning as a via are connected by the conductor connecting section 11.

Next, the insulating resin layer integration step shown in FIGS. 5(C) to 5(E) is performed to integrate the metal circuit layer 4 with an insulating resin layer. The circuit layer removal member 5 such as an adhesive sheet or a suction sheet is adhered to the other face 4a at an opposite side of the concavo-convex face of the metal circuit layer 4. Then, this circuit layer removal member 5 is peeled to remove, as shown in FIG. 5(C), the metal circuit layer 4 from the metal mold 1. The metal circuit layer 4 removed from the metal mold 1 has a concavo-convex face in which the concavo-convex pattern formed in the metal mold 1 has a transferred concavo-convex shape and the first conductor circuit 6 and the interlayer connecting section 7 are simultaneously formed in an integrated manner. The interlayer connecting section 7 is a convex section having a higher height than that of the first conductor circuit 6.

Next, the insulating resin layer 8 shown in FIG. 5(D) is prepared and is placed to be opposed to the concavo-convex face of the metal circuit layer 4. The insulating resin layer 8 may be formed, for example, by liquid crystal polymer film (thermoplastic resin). When the insulating resin layer 8 is formed not by thermoplastic resin but by thermoset resin, the insulating resin layer 8 may be formed by half-cured thermoset resin. In the fourth embodiment of the present invention, the insulating resin layer 8 was formed by a liquid crystal polymer film. Then, the concavo-convex face of the metal circuit layer 4 is superposed on the insulating resin layer 8 and the resultant structure is pressurized and heated. The pressurization and heating were carried out under conditions of pressurizing and heating the metal circuit layer 4 and the insulating resin layer 8 at a temperature of 270 degrees C. and a pressurization force of 10 MPa for 10 minutes. 30 minutes are required to reach the heating temperature of 270 degrees C. and 60 minutes are required to cool the resin to room temperature.

The result is as shown in FIG. 5(E) in which the metal circuit layer 4 is firmly integrated with the insulating resin layer 8. The first conductor circuit 6 is embedded in the one face 8a of the insulating resin layer 8. The interlayer connecting section 7 penetrates the insulating resin layer 8 to expose the tip end 7a thereof at the same height as that of the other face 8b (i.e., to be flush to each other). After the integration of the metal circuit layer 4 and the insulating resin layer 8, the metal circuit layer 4 is removed from the circuit layer removal member 5.

Next, the polishing step shown in FIG. 5(F) is performed. Specifically, the metal circuit layer 4 superposed on the one face 8a at the superposed side of the insulating resin layer 8 is polished until the resin of the insulating resin layer 8 is exposed. The polishing is performed by polishing the metal circuit layer 4 by a grinding stone or by melting the metal circuit layer 4 by etching. As a result, the connected conductor connecting section 11 (the conductor portion other than the circuit) is removed to thereby form the first conductor circuit 6 and the interlayer connecting section 7. The interlayer connecting section 7 is conductive with the first conductor circuit 6 and penetrates the insulating resin layer 8 to expose the tip end 7a at the other face 8b.

Next, the circuit formation step shown in FIG. 5(G) is performed. Specifically, on the other face 8b of the insulating resin layer 8 exposed through polishing, the second conductor circuit 9 is formed that is formed on the one face 8a of the insulating resin layer 8 via the interlayer connecting section 7 and that is conductive with the first conductor circuit 6. In order to form the second conductor circuit 9, the second conductor circuit 9 is positioned to the interlayer connecting section 7 so as to be connected to the interlayer connecting section 7 and a wiring pattern is formed by photolithography or printing for example. In the fourth embodiment of the present invention, the wiring pattern was formed by the semiadditive process so as to achieve the wiring width of 10 μm, a space between wirings of 10 μm, and a land diameter of 80 μm. By the formation as described above, the double face circuit substrate 10 is obtained in which the first conductor circuit 6 is connected via the interlayer connecting section 7 to the second conductor circuit 9. Then, solder resist or a coverlay is provided as required on the surface of this double face circuit substrate 10.

The polishing step shown in FIG. 5(F) can be omitted if an excessive portion as the conductor connecting section 11 can be eliminated by optimizing the conditions to fill the conducting metal material in FIG. 5(B).

In the fourth embodiment, the first concave section 2 and the second concave section 3 formed in the metal mold 1 are filled with the conducting metal material and the conducting metal material is cured to thereby form the metal circuit layer 4. Then, the concavo-convex face of the metal circuit layer 4 is superposed on the insulating resin layer 8 and the resultant structure is pressurized and heated to thereby integrate the metal circuit layer 4 with the insulating resin layer 8. Thus, this metal circuit layer 4 itself functions as the first conductor circuit 6 and the interlayer connecting section 7. The interlayer connecting section 7 functions as a via that electrically connects the first conductor circuits 6 to the second conductor circuit 9, the first and second conductor circuits being formed on respective faces of the insulating resin layer 8. This consequently eliminates the need as in the conventional case of using a stamper (mold) to transfer a concavo-convex pattern on insulating resin to subsequently subject the resin to a plating process for example to thereby form a conductor circuit and an interlayer connecting section. Thus, there is no more need to perform a step of manufacturing a stamper (mold). This can consequently prevent a failure caused by resin being attached to a stamper (mold), because a situation will not occur in which the resin is being attached to the stamper (mold) when a stamper (mold) is demolded from the insulating resin layer. Furthermore, a plating step is also not required to fill the concave section transferred on the insulating resin layer with the conducting material. Thus, the manufacture step can be simplified significantly and the cost can be proportionally reduced.

Also according to the fourth embodiment, the first conductor circuit 6 and the interlayer connecting section 7 can be simultaneously formed by a single step. Thus, when compared with the conventional method to separately form the first conductor circuit 6 and the interlayer connecting section 7, the first conductor circuit 6 and the interlayer connecting section 7 can be positioned with an improved accuracy.

Also according to the fourth embodiment, by the use of the conducting paste of conducting metal material filled in the first concave section 2 and the second concave section 3 formed on the metal mold 1, the metal circuit layer 4 can be easily formed without causing increased manhours.

The wiring substrate formed by the manufacture method of the fourth embodiment is structured so that the first conductor circuit 6 is formed on the one face 8a of the insulating resin layer 8 and the interlayer connecting section 7 functioning as a via connected to the first conductor circuit 6 penetrates the insulating resin layer 8 to expose the tip end thereof at the other face 8b. In this wiring substrate, as shown in FIG. 5(G), the first conductor circuit 6 and the interlayer connecting section 7 are formed of the same conducting metal material simultaneously. Thus, there is no interface between the first conductor circuit 6 and the interlayer connecting section 7. In the case of the wiring substrate obtained through the conventional manufacture method, the conductor circuit and the interlayer connecting section are formed by separate steps and thus always have an interface therebetween.

If the first conductor circuit 6 and the interlayer connecting section 7 do not have an interface therebetween, the first conductor circuit 6 and the interlayer connecting section 7 can have an increased strength therebetween and an electric loss at an interface can be reduced, thus improving the electric communication status. If the first conductor circuit 6 and the interlayer connecting section 7 have an interface therebetween on the other hand, a weak strength is caused when the wiring substrate receives an external force, thus causing a risk of a deteriorated electric communication status.

The wiring substrate manufactured according to the manufacture method of the fourth embodiment is configured so that the first conductor circuit 6 formed on the one face 8a of the insulating resin layer 8 is at the same height as that of the one face 8a (i.e., the former and the latter are flush to each other) and the tip end 7a of the interlayer connecting section 7 exposed at the other face 8b of the insulating resin layer 8 is at the same height as that of the other face 8b (i.e., the former and the latter are flush to each other). As described above, since the first conductor circuit 6 and the interlayer connecting section 7 do not protrude from both faces 8a and 8b of the insulating resin layer 8, the wiring substrate can be thinner.

### Fifth Embodiment

The fifth embodiment is an example in which a layered wiring substrate is manufactured by further layering another circuit on the double face circuit substrate 10 manufactured in the fourth embodiment. The steps up to the step of forming the double face circuit substrate 10 are the same as those in the fourth embodiment. Thus, the metal circuit layer formation step of the fourth embodiment will be called as the first metal circuit layer formation step and the metal circuit layer 4 will be called as the first metal circuit layer. The insulating resin layer integration step of the fourth embodiment will be called as the first insulating resin layer integration step and the insulating resin layer will be called as the first insulating resin layer. The polishing step of the fourth embodiment will be called as the first polishing step and the interlayer connecting section 7 will be called as the first interlayer connecting section 7.

First, the respective manufacture steps of the fourth embodiment (the first metal circuit layer formation step, the first insulating resin layer integration step, the first polishing step, and the double face circuit substrate formation step) are performed to prepare the double face circuit substrate 10. The double face circuit substrate 10 is structured so that the first insulating resin layer 8 has the first conductor circuit 6 and the second conductor circuit 9 respectively on each of the faces thereof, and has the first interlayer connecting section 7 which penetrates the first insulating resin layer 8 to electrically connect the first conductor circuit 6 to the second conductor circuit 9.

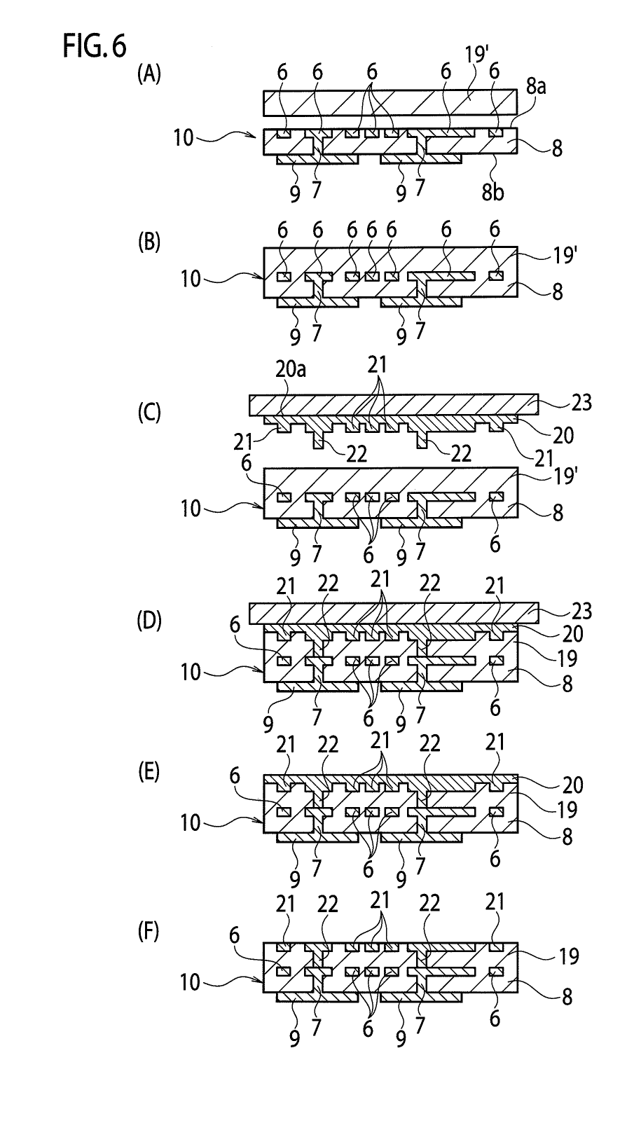

Next, as shown in FIGS. 6(A) and 6(B), the face 8a of the double face circuit substrate 10 on which the first conductor circuit 6 is formed is superposed on the half-cured second insulating resin layer 19′. The half-cured second insulating resin layer 19′ is a half-cured epoxy resin film for example. Next, the second metal circuit layer formation step, which is the same step as the first metal circuit layer formation step of the fourth embodiment, is performed to form the second metal circuit layer 20. In the fifth embodiment, the second metal circuit layer 20 has the same shape as that of the metal circuit layer 4 formed in the fourth embodiment. Thus, the metal mold 1 used in FIG. 5(A) is used. The metal mold 1 also may be another metal mold. As shown in FIG. 6(C), the second metal circuit layer 20 has the third conductor circuit 21 and the second interlayer connecting section 22 that are simultaneously and collectively formed. The third conductor circuit 21 corresponds to the first conductor circuit 6 formed in the fourth embodiment. The second interlayer connecting section 22 corresponds to the first interlayer connecting section 7.

The second metal circuit layer 20 also has the circuit layer removal member 23 consisting of an adhesive sheet or a suction sheet for example for removing the second metal circuit layer 20 from the metal mold. The circuit layer removal member 23 is adhered on the other face 20a at an opposite side of the concavo-convex face.

Next, as shown in FIG. 6(D), the concavo-convex face of the second metal circuit layer 20 is superposed on the half-cured second insulating resin layer 19′ to pressurize and heat the second metal circuit layer 20 and the double face circuit substrate 10 to thereby provide the cured second insulating resin layer 19. Then, the second metal circuit layer 20 is integrated with the double face circuit substrate 10. Prior to the pressurization of the second metal circuit layer 20 and the double face circuit substrate 10, the second metal circuit layer 20 and the double face circuit substrate 10 are respectively positioned by an image recognition or pin alignment for example to match the marks formed on the second metal circuit layer 20 and the double face circuit substrate 10 so that the second interlayer connecting section 22 can be connected to a land formed on the first conductor circuit 6.

After the pressurization of the second metal circuit layer 20 and the double face circuit substrate 10, the concavo-convex section of the second metal circuit layer 20 is firmly integrated with the half-cured second insulating resin layer 19′ and the third conductor circuit 21 is embedded in the second insulating resin layer 19′ and the second interlayer connecting section 22 penetrates the second insulating resin layer 19′ to thereby allow the tip end thereof to be abutted to the land of the first conductor circuit 6. As a result, the third conductor circuit 21 is electrically connected to the second conductor circuit 9 via the second interlayer connecting section 22 and the first interlayer connecting section 7. Then, the second metal circuit layer 20 and the double face circuit substrate 10 are integrated by the second insulating resin layer 19 cured by heating.

Next, as shown in FIG. 6(E), the circuit layer removal member 23 is removed from the second metal circuit layer 20. Next, the second polishing step is performed to polish the second metal circuit layer 20. In the second polishing step, as in the first polishing step of the fourth embodiment, the second metal circuit layer 20 is polished by a grinding stone or by etching until resin is exposed. The result is as shown in FIG. 6(F) in which the connected conductor connecting section 11 (the conductor portion other than the circuit) is removed to thereby form the third conductor circuit 21 and the second interlayer connecting section 22. The second interlayer connecting section 22 is conductive with the third conductor circuit 21 and penetrates the second insulating resin layer 19 to be electrically connected to the land of the first conductor circuit 6.

The layered wiring substrate manufactured in the manner as described above is configured so that the first conductor circuit 6 is electrically connected to the second conductor circuit 9 through the first interlayer connecting section 7 functioning as a via and the first conductor circuit 6 is electrically connected to the third conductor circuit 21 through the second interlayer connecting section 22 also functioning as a via.

In the fifth embodiment, the half-cured second insulating resin layer 19′ is superposed on one face of the double face circuit substrate 10 formed by the step of using the metal mold to simultaneously and collectively form the first conductor circuit 6 and the first interlayer connecting section 7. Thereafter, the second metal circuit layer 20 obtained by further simultaneously and collectively forming the third conductor circuit 21 and the second interlayer connecting section 22 is pressurized to the second insulating resin layer 19′ and heated for integration to thereby provide a conductor circuit having a multilayered structure without requiring a complicated step. Also according to the manufacture method of the fifth embodiment, a conductor circuit of four or more layers can be formed.

In the fifth embodiment, as in the fourth embodiment, the metal circuit layer itself constitutes a conductor circuit and an interlayer connecting section as a via. Thus, there is no more need as in the conventional case to use a stamper (mold) to transfer a concavo-convex pattern on insulating resin to subsequently subject the resin to a plating process for example to thereby form a conductor circuit and an interlayer connecting section. Thus, a step to manufacture a stamper (mold) can be eliminated. This can consequently prevent a failure caused by resin being attached to a stamper (mold), because a situation will not occur in which the resin is being attached to the stamper (mold) when a stamper (mold) is demolded from the insulating resin layer. Furthermore, a plating step is also not required to fill the concave section of the insulating resin layer on which the concavo-convex pattern of the stamper (mold) is transferred. Thus, the manufacture step can be simplified significantly and the cost can be proportionally reduced.

In the fifth embodiment, as in the fourth embodiment, the first conductor circuit 6 and the first interlayer connecting section 7, the third conductor circuit 21, and the second interlayer connecting section 22 can be formed simultaneously and collectively. Thus, when compared with the conventional method of separately forming the first conductor circuit 6 and the first interlayer connecting section 7, the third conductor circuit 21, and the second interlayer connecting section 22, the first conductor circuit 6 and the first interlayer connecting section 7, the third conductor circuit 21, and the second interlayer connecting section 22 can be positioned with an improved accuracy.

### Sixth Embodiment

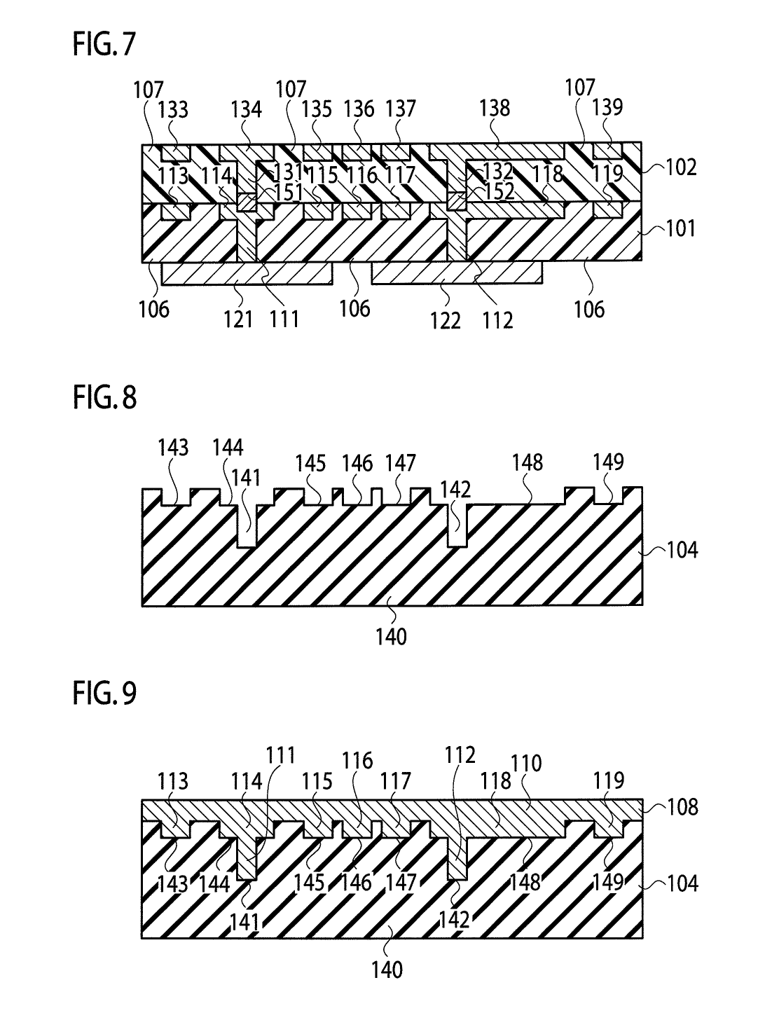

A wiring substrate according to the sixth embodiment of the present invention is, as shown in FIG. 7, a multilayered substrate that includes the first substrate 101 and the second substrate 102 formed on the upper face of the first substrate 101.

The first substrate 101 includes: the first insulating resin layer 106; the first conductor circuits 113 to 119 embedded in the upper part of the first insulating resin layer 106; the second conductor circuits 121 and 122 placed on the lower face of the first insulating resin layer 106; and the first interlayer connecting sections 111 and 112 that connect the first conductor circuits 114 and 118 to the second conductor circuits 121 and 122. The first conductor circuits 114 and 118 and the first interlayer connecting sections 111 and 112 have therebetween no interface. Thus, the first conductor circuits 114 and 118 are integrated with the first interlayer connecting sections 111 and 112.

The second substrate 102 includes: the second insulating resin layer 107 layered on the first insulating resin layer 106; the third conductor circuits 133 to 139 embedded in the upper part of the second insulating resin layer 107; and the second interlayer connecting sections 131 and 132 connected to the third conductor circuits 134 and 138. The third conductor circuits 134 and 138 and the second interlayer connecting sections 131 and 132 have therebetween no interface. Thus, the third conductor circuits 134 and 138 are integrated with the second interlayer connecting sections 131 and 132.

The first insulating resin layer 106 and the second insulating resin layer 107 may be formed by material such as thermoset resin (e.g., epoxy resin) or thermoplastic resin (e.g., liquid crystal polymer). The first conductor circuits 113 to 119, the second conductor circuits 121 and 122, the third conductor circuits 133 to 139, the first interlayer connecting sections 111 and 112, and the second interlayer connecting sections 131 and 132 can be formed by material such as copper (Cu) or silver (Ag).

In the sixth embodiment of the present invention, the second interlayer connecting sections 131 and 132 and the first conductor circuits 114 and 118 have therebetween alloy layers 151 and 152. The alloy layers 151 and 152 are obtained by melting a soldering layer including copper (Cu), silver (Ag), and tin (Sn) for example to provide the alloy of the material of the second interlayer connecting sections 131 and 132 and the material of the first conductor circuits 114 and 118 including copper (Cu), silver (Ag), and tin (Sn) for example.

According to the wiring substrate of the sixth embodiment of the present invention, the existence of the alloy layers 151 and 152 provided between the second interlayer connecting sections 131 and 132 and the first conductor circuits 114 and 118 can prevent a crack from occurring in an interface between the second interlayer connecting sections 131 and 132 and the first conductor circuits 114 and 118, thus reducing the signal loss. Thus, the second interlayer connecting sections 131 and 132 and the first conductor circuits 114 and 118 can have therebetween an improved connection reliability.

Next, the following section will describe an example of a method of manufacturing a wiring substrate according to the sixth embodiment of the present invention with reference to FIG. 8 to FIG. 20.

(i) First, the first substrate 101 shown in FIG. 7 is prepared by the steps shown in FIG. 8 to FIG. 16. As shown in FIG. 8, the metal mold 104 is prepared. The metal mold 104 is made of material that can be easily demolded from conducting material or that is coated with a surface treatment. The metal mold 104 includes: a base 140; concave sections 143 to 149 provided at the upper part of the base 140; and holes 141 and 142 communicating with the concave sections 143 to 149. Although the metal mold 104 can be manufactured by various methods, if a particularly-minute size is required, resist is coated on a silicon (Si) substrate having thereon a seed layer and the resist is drawn and developed by an electron beam (EB), ultraviolet light (UV), or laser and is patterned. The series of steps are repeated to fill the patterned concavo-convex section with conducting material by a plating using nickel (Ni) or copper (Cu) for example. Thereafter, the resist can be removed to thereby manufacture the metal mold 104. The surface of the metal mold 104 can be subjected, as required, to a demolding processing by a commercially-available fluorine silan coupling agent.

(ii) As shown in FIG. 9, the holes 141 and 142 and the concave sections 143 to 149 of the metal mold 104 are subjected to sputtering by copper (Cu) or nickel (Ni) for example or a Direct Plating Processing (DPP) using carbon (C) or palladium (Pd) for example. Then, the plating by copper (Cu) or nickel (Ni) for example or the printing and sintering of the nanopaste of copper (Cu) or silver (Ag) for example is performed to fill conducting material. As a result, the first metal circuit layer 108 is formed. The first metal circuit layer 108 has: the first support section 110 that is formed on the metal mold 104 and that consists of conducting material; the first conductor circuits 113 to 119 that are filled in the concave sections 143 to 149 and that consist of conducting material; and the first interlayer connecting sections 111 and 112 that are filled in the holes 141 and 142 and that consist of conducting material. In the sixth embodiment of the present invention, resist is patterned by i-ray exposure to thereby manufacture the metal mold 104. As a result, the first interlayer connecting sections 111 and 112 have a shape having a diameter of about 10 μm and a height of about 25 μm. Among the first conductor circuits 113 to 119, the line and space part has a wiring width of about 5 μm, a wiring interval of about 5 μm, and a land diameter of about 30 μm. By optimizing the conditions to fill conducting material, only the first conductor circuits 113 to 119 and the first interlayer connecting sections 111 and 112 also may be formed without forming the first support section 110. A support tool 105 such as an adhesive sheet or an adsorption stage is used to remove the first metal circuit layer 108 from the metal mold 104 as shown in FIG. 10. FIG. 11 is a perspective view illustrating the first support section 110, the first conductor circuit 118, and the first interlayer connecting section 112 constituting a part of the first metal circuit layer 108 seen from the lower face side.

(iii) As shown in FIG. 12, the first insulating resin layer 106 is prepared that consists of uncured thermoset resin (e.g., epoxy resin) or thermoplastic resin (e.g., liquid crystal polymer). Then, the support tool 105 is used to oppose the upper face of the first insulating resin layer 106 to the face of the first metal circuit layer 108 on which the first conductor circuits 113 to 119 and the first interlayer connecting sections 111 and 112 are formed. As shown in FIG. 13, to the first insulating resin layer 106 heated to the softening temperature, the first conductor circuits 113 to 119 and the first interlayer connecting sections 111 and 112 are press-fitted and are heated and pressed in the layering direction. In the sixth embodiment of the present invention, a liquid crystal polymer film is used as the first insulating resin layer 106, and the film is pressed at 270 degrees C. and 10 MPa for 10 minutes. This process requires another 30 minutes to increase the temperature to 270 degrees C. and one hour to cool the temperature to room temperature. Thereafter, the support tool 105 is removed from the first metal circuit layer 108 as shown in FIG. 14.

(iv) Since the first support section 110 of the first metal circuit layer 108 is an excessive part, the first support section 110 is removed by polishing or etching for example as shown in FIG. 15. This polishing or etching step also can be omitted by optimizing the conditions shown in FIG. 9 to fill conducting material to thereby not to form the first support section 110.

(v) As shown in FIG. 16, the second conductor circuits 121 and 122 are formed on the lower face of the first insulating resin layer 106 by the photolithography technique and printing for example to thereby complete the first substrate 101. In the sixth embodiment of the present invention, the semiadditive process is used to form the line and space part of the second conductor circuits 121 and 122 to have a wiring width of about 10 μm, a wiring interval of about 10 μm, and a land diameter of about 80 μm.

(vi) As shown in FIG. 17, the second insulating resin layer 107 is prepared. Then, the second insulating resin layer 107 that has a sheet-like shape and that consists of uncured thermoset resin (e.g., epoxy resin) or thermoplastic resin (e.g., liquid crystal polymer) is superposed on the first substrate 101 to thereby perform layering (lamination) as shown in FIG. 18. The second insulating resin layer 107 is formed by material that has a softening point lower than a melting point of 220 degrees C. of the soldering layer functioning as the alloy layers 151 and 152 shown in FIG. 7.

(vii) As shown in FIG. 19, the second metal circuit layer having the third conductor circuit 133 to 139 and the second interlayer connecting sections 131 and 132 is prepared. The second metal circuit layer can be formed by the steps shown in FIG. 8 to FIG. 10 to form the first metal circuit layer 108. The second metal circuit layer is obtained by optimizing the conditions to fill conducting material to form the third conductor circuits 133 to 139 and the second interlayer connecting sections 131 and 132 without forming an excessive part (e.g., the first support section 110 of the metal mold 104 shown in FIG. 9). The second metal circuit layer also may be the one obtained by the metal mold 104 to have the same pattern shape as that of the first metal circuit layer 108. Alternatively, the second metal circuit layer also may be the one obtained by a different metal mold from the metal mold 104 to have the same pattern shape with or a different pattern shape from that of the first metal circuit layer 108. As shown in FIG. 19, plating or printing for example is used to form soldering layers 161 and 162 on the top parts of the second interlayer connecting sections 131 and 132, respectively. The soldering layers 161 and 162 may be formed by material such as alloy of tin (Sn), silver (Ag), and copper (Cu). In the sixth embodiment of the present invention, the soldering layers 161 and 162 are formed by soldering paste consisting of tin (Sn)-1 silver (Ag)-0.5 copper (Cu) and flux and are printed to achieve about 1 μm and are sintered in a reflow furnace.

(viii) The support tool 105 is used to place the third conductor circuit 133 to 139 and the second interlayer connecting sections 131 and 132 to be opposed to the upper face of the second insulating resin layer 107. An image recognition or pin alignment for example is used to position the third conductor circuit 133 to 139 and the second interlayer connecting sections 131 and 132 with the first conductor circuits 113 to 119 opposed thereto. Then, as shown in FIG. 20, to the second insulating resin layer 107 heated up to the softening temperature, the third conductor circuits 133 to 139 and the second interlayer connecting sections 131 and 132 are press-fitted. The first substrate 101 and the second insulating resin layer 107 are heated and pressed in the layering direction. As a result, the soldering layers 161 and 162 are abutted to the first conductor circuits 114 and 118. By this heating, the second insulating resin layer 107 is completely cured if the second insulating resin layer 107 is thermoset resin. If the second insulating resin layer 107 is composed of thermoplastic resin, the second insulating resin layer 107 is cured by being subsequently cooled. By this heating, the soldering layers 161 and 162 are also molten to form the alloy layers 151 and 152 between the second interlayer connecting sections 131 and 132 and the first conductor circuits 114 and 118, thereby completing the multilayered substrate shown in FIG. 7. If the second metal circuit layer has an excessive part after the removal of the support tool 105, the excessive part is removed by polishing or etching for example.

According to the sixth embodiment of the present invention, the third conductor circuits 133 to 139 and the second interlayer connecting sections 131 and 132 are embedded in the second insulating resin layer 107. This can prevent a failure caused by resin being attached to a stamper (mold), because a situation will not occur in which the resin is being attached to the stamper (mold) when a stamper (mold) is demolded from the insulating resin layer. In the case of a conventional wiring substrate, a crack or signal loss may be caused at an interface between an interlayer connecting section and a conductor circuit, thus causing a difficulty in maintaining the connection reliability between the interlayer connecting section and the conductor circuit. According to a method of manufacturing a wiring substrate of the sixth embodiment of the present invention, the existence of the alloy layers 151 and 152 formed between the second interlayer connecting sections 131 and 132 and the first conductor circuits 113 to 119 can be used to manufacture a wiring substrate in which an improved connection reliability can be achieved between the second interlayer connecting sections 131 and 132 and the first conductor circuits 113 to 119.

### Seventh Embodiment

As the seventh embodiment of the present invention, another example of a wiring substrate will be described. As shown in FIG. 21, the wiring substrate according to the seventh embodiment of the present invention is a double face substrate that includes: an insulating resin layer 200; the first conductor circuits 213 to 219 embedded in the upper part of the insulating resin layer 200; the second conductor circuits 221 and 222 placed on the lower face of the insulating resin layer 200; the interlayer connecting sections 211 and 212 for connecting the first conductor circuits 214 and 218 to the second conductor circuits 221 and 222; and alloy layers 251 and 252 formed between the interlayer connecting sections 211 and 212 and the second conductor circuits 221 and 222. The first conductor circuits 214 and 218 and the interlayer connecting sections 211 and 212 have therebetween no interface. Thus, the first conductor circuits 214 and 218 are integrated with the interlayer connecting sections 211 and 212.

According to the wiring substrate of the seventh embodiment of the present invention, the existence of the alloy layers 251 and 252 provided between the second conductor circuits 221 and 222 and the interlayer connecting sections 211 and 212 can improve connection reliability between the second conductor circuits 221 and 222 and the interlayer connecting sections 211 and 212.

A method of manufacturing a wiring substrate according to the seventh embodiment of the present invention is performed, through the steps similar to those shown in FIG. 19 to FIG. 20, to provide a configuration as shown in FIG. 22 in which the first conductor circuits 213 to 219 are embedded in the upper part of the insulating resin layer 200, the interlayer connecting sections 211 and 212 penetrate the insulating resin layer 200, and the soldering layers 261 and 262 are protruded from the lower face of the insulating resin layer 200. Thereafter, the photolithography technique and printing for example are used to form, as shown in FIG. 21, the second conductor circuits 221 and 222 on the lower face of the insulating resin layer 200. Thereafter, the soldering layers 261 and 262 are molten by heating to thereby allow the interlayer connecting sections 211 and 212 and the second conductor circuits 221 and 222 to have therebetween the alloy layers 251 and 252. The alloy layers 251 and 252 consist of the material of the soldering layers 261 and 262 and the materials of the interlayer connecting sections 211 and 212 and the second conductor circuits 221 and 222.

According to the seventh embodiment of the present invention, the first conductor circuits 213 to 219 and the interlayer connecting sections 211 and 212 are embedded in the upper face of the insulating resin layer 200. This can prevent a failure conventionally caused by resin being attached to a stamper (mold), because a situation will not occur in which the resin is being attached to the stamper (mold) when a stamper (mold) is demolded from the insulating resin layer. Furthermore, the existence of the alloy layers 251 and 252 formed between the second conductor circuits 221 and 222 and the interlayer connecting sections 211 and 212 can be used to manufacture a double face substrate in which a high connection reliability is achieved between the second conductor circuits 221 and 222 and the interlayer connecting sections 211 and 212.

### Other Embodiments

Various modifications will become possible for those skilled in the art after receiving the teachings of the present disclosure without departing from the scope thereof. FIGS. 23(A) to 23(F) illustrate the other embodiments.

FIGS. 23(A) to 23(F) are a step diagram illustrating the steps of forming a metal circuit layer having a minute conductor circuit pattern. FIG. 23(A) illustrates a silicon wafer preparation step. FIG. 23(B) illustrates a concavo-convex pattern formation step by resist. FIG. 23(C) illustrates a seed layer formation step. FIG. 23(D) illustrates a plating step. FIG. 23(E) illustrates a plating polishing step. FIG. 23(F) illustrates a step of removing the metal circuit layer from the silicon wafer.

When the first conductor circuit 6 and the interlayer connecting section 7 require a minute conductor circuit pattern, the steps shown in FIGS. 23(A) to 23(F) are performed to manufacture the metal circuit layer 17. First, as shown in FIG. 23(A), a silicon wafer 12 is prepared.

Next, after resist is coated on the one face 12a of the silicon wafer 12, this resist is subjected to photolithography by exposure and development to thereby form a penetration hole reaching the one face 12a. Thereafter, resist is further coated on the resist and then the second photolithography is performed to thereby form, as shown in FIG. 23(B), the first concave section 14 and the second concave section 15 on the cured resist layer 13. The second concave section 15 has a deeper depth than that of the first concave section 14 and reaches the one face 12a. Next, as shown in FIG. 23(C), copper or nickel for example is sputtered on the resist layer 13 having a concavo-convex shape by the first concave section 14 and the second concave section 15 to thereby form a seed layer 16.

Next, as shown in FIG. 23(D), copper for example is plated on the seed layer 16 so that the first concave section 14 and the second concave section 15 are both embedded to thereby form a metal circuit layer 17. Then, as shown in FIG. 23(E), the one face 17a constituting the surface of the metal circuit layer 17 is polished to subject the surface to a smoothing process.

Next, the circuit layer removal member 18 (e.g., an adhesive sheet or a suction sheet) is adhered on the one face 17a of the metal circuit layer 17 at an opposite side of the concavo-convex face. Then, this circuit layer removal member 18 is peeled to thereby remove, as shown in FIG. 23(F), the metal circuit layer 17 from the resist layer 13. The metal circuit layer 17 removed from the resist layer 13 has a concavo-convex face on which the concavo-convex pattern formed on the resist layer 13 is transferred. Thus, the first conductor circuit 6 is integrated with the interlayer connecting section 7.

Alternatively, the wiring substrate according to the seventh embodiment of the present invention shown in FIG. 21 also may be used instead of the first substrate 101 shown in FIG. 7.

As in the soldering layers 161 and 162 formed on the top parts of the interlayer connecting sections 131 and 132 shown in FIG. 19, soldering layers also may be formed on the top part of the interlayer connecting section 7 shown in FIG. 1(F), the top part of the interlayer connecting section 22 shown in FIG. 3(B), the top part of the interlayer connecting section 22 shown in FIG. 4(A), the top part of the interlayer connecting section 7 shown in FIG. 5(C), and the top part of the interlayer connecting section 22 shown in FIG. 6(C).

With regard to the double face circuit substrate 10 shown in FIG. 3(C) in the second embodiment and the double face circuit substrate 10 shown in FIG. 4(A) in the third embodiment, the double face circuit substrate 10 shown in FIG. 1(G) manufactured in the first embodiment by the coating of liquid insulating resin also may be substituted with the double face circuit substrate 10 shown in FIG. 5(G) manufactured in the fourth embodiment by press-fitting the conductor circuit 6 and the interlayer connecting section 7 to the insulating resin layer 8, respectively.

With regard to the double face circuit substrate 10 shown in FIG. 6(A) in the fifth embodiment, the double face circuit substrate 10 shown in FIG. 5(G) manufactured in the fourth embodiment by press-fitting the conductor circuit 6 and the interlayer connecting section 7 to the insulating resin layer 8 also may be substituted with the double face circuit substrate 10 shown in FIG. 1(G) manufactured by coating liquid insulating resin in the first embodiment.

The double face circuit substrate shown in FIG. 17 in the sixth embodiment also may be substituted with the double face circuit substrate 10 shown in FIG. 1(G) manufactured in the first embodiment by coating liquid insulating resin or the double face circuit substrate 10 shown in FIG. 5(G) manufactured in the fourth embodiment by press-fitting the conductor circuit 6 and the interlayer connecting section 7 to the insulating resin layer 8.

### INDUSTRIAL APPLICABILITY

The present invention can be used for a wiring substrate in which at least a conductor circuit formed on one face of an insulating substrate is connected by an interlayer connecting section functioning as a via.

What is claimed is:

1. A method of manufacturing a wiring substrate, comprising:
a step of preparing a first metal circuit layer, one face of the first metal circuit layer has thereon a first conductor circuit and a first interlayer connecting section having a different height from that of the first conductor circuit; and
a step of forming a first insulating resin layer covering the one face of the first metal circuit layer so that a tip end of the first interlayer connecting section is exposed.

2. The method of manufacturing a wiring substrate according to claim 1, wherein the step of forming the first insulating resin layer includes coating and curing liquid insulating resin on the one face of the first metal circuit layer to embed the first conductor circuit in one face of the first insulating resin layer and exposing a tip end of the first interlayer connecting section at the other face of the first insulating resin layer.

3. The method of manufacturing a wiring substrate according to claim 1, wherein the step of forming the first insulating resin layer includes superposing the one face of the first metal circuit layer on one face of the first insulating resin layer and pressurizing and heating a resultant structure to thereby embed the first conductor circuit in the one face of the first insulating resin layer and to expose a tip end of the first interlayer connecting section at the other face of the first insulating resin layer.

4. The method of manufacturing a wiring substrate according to claim 2, further comprising:
a step of forming a second conductor circuit in the other face of the first insulating resin layer, the second conductor circuit being conductive with the first conductor circuit via the first interlayer connecting section.

5. The method of manufacturing a wiring substrate according to claim 1, wherein
the step of preparing the first metal circuit layer includes:
preparing a metal mold having a first concave section for forming the first conductor circuit and a second concave section, the second concave section having a deeper depth than that of the first concave section and being used to form a first interlayer connecting section;
filling and curing conducting metal material in the first and second concave sections to thereby form the first metal circuit layer; and
removing the first metal circuit layer from the metal mold.

6. The method of manufacturing a wiring substrate according to claim 5, wherein the conducting metal material is conducting paste.

7. The method of manufacturing a wiring substrate according to claim 4, further comprising:
a step of preparing a second metal circuit layer, one face of the second metal circuit layer has thereon a third conductor circuit and a second interlayer connecting section having a different height from that of the third conductor circuit;
a step of coating and half-curing liquid insulating resin on the one face of the second metal circuit layer to thereby embed the third conductor circuit in one face of a second insulating resin layer and to expose a tip end of the second interlayer connecting section at the other face of the second insulating resin layer; and
a step of superposing the one face of the first insulating resin layer in which the first conductor circuit is embedded with the other face of the second insulating resin layer at which the tip end of the second interlayer connecting section is exposed to heat and pressurize a resultant structure to thereby cure the second insulating resin layer so that the first conductor circuit is abutted to the second interlayer connecting section.

8. The method of manufacturing a wiring substrate according to claim 4, further comprising:
a step of preparing a second metal circuit layer, one face of the second metal circuit layer has a third conductor circuit and a second interlayer connecting section having a different height from that of the third conductor circuit;
a step of superposing the one face of the first insulating resin layer in which the first conductor circuit is embedded with one face of the half-cured second insulating resin layer; and
a step of superposing the one face of the second metal circuit layer with the other face of the second insulating resin layer to pressurize and heat a resultant structure to thereby cure the half-cured second insulating resin layer and embedding the third conductor circuit in the other face of the second insulating resin layer so that a tip end of the second interlayer connecting section is abutted to the first conductor circuit.

9. The method of manufacturing a wiring substrate according to claim 4, further comprising:
a step of superposing one face of a second insulating resin layer on the one face of the first insulating resin layer in which the first conductor circuit is embedded;
a step of preparing a second metal circuit layer, one face of the second metal circuit layer has a third conductor circuit and a second interlayer connecting section having a different height from that of the third conductor circuit;
a step of forming a soldering layer on a top part of the second interlayer connecting section;
a step of press-fitting the third conductor circuit and the second interlayer connecting section of the second metal circuit layer to the other face of the second insulating resin layer so that the soldering layer is abutted to the first conductor circuit; and
a step of melting the soldering layer to form an alloy layer between the second interlayer connecting section and the first conductor circuit.

10. A method of manufacturing a wiring substrate, comprising:
a step of forming a metal circuit layer, one face of the metal circuit layer has a first conductor circuit and an interlayer connecting section having a different height from that of the first conductor circuit;
a step of forming a soldering layer on a top part of the interlayer connecting section;
a step of preparing an insulating resin layer;
a step of press-fitting, to one face of the insulating resin layer, the interlayer connecting section in which the first conductor circuit and the soldering layer are formed at the top part to expose the soldering layer from the other face of the insulating resin layer;
a step of forming, on the other face of the insulating resin layer, a second conductor circuit abutted to the soldering layer; and
a step of melting the soldering layer to form an alloy layer between the interlayer connecting section and the second conductor circuit.
